(19) United States
(12) Patent Application Publication
(10) Pub. No.: US 2019/0149734 A1
(43) Pub. Date: May 16, 2019

(54) ARITHMETIC PROCESSING DEVICE, IMAGE PROCESSING DEVICE, AND IMAGING DEVICE

(71) Applicant: OLYMPUS CORPORATION, Tokyo (JP)

(72) Inventors: Takashi Yanada, Tokyo (JP); Akira Ueno, Tokyo (JP)

(73) Assignee: OLYMPUS CORPORATION, Tokyo (JP)

(21) Appl. No.: 16/244,525

(22) Filed: Jan. 10, 2019

Related U.S. Application Data
(63) Continuation of application No. PCT/JP2016/073431, filed on Aug. 9, 2016.

(51) Int. Cl. H04N 5/232; H04N 1/21; G06F 7/76

(52) U.S. Cl. CPC H04N 5/23245; H03K 19/20; G06F 7/764; H04N 1/212

(57) ABSTRACT

An arithmetic processing device of a pipeline configuration in which a combination of a combination circuit and a flip-flop circuit group including a plurality of flip-flop circuits corresponding to each bits of output data of the combination circuit is connected in a plurality of stages includes a mask processing section configured to control a mask of an operation clock signal to be supplied to each flip-flop circuit, wherein the mask processing section is configured to supply the operation clock signal to each flip-flop circuit corresponding to a bit of the input data for use in the arithmetic process in the combination circuit, and wherein the mask processing section is configured to mask the operation clock signal corresponding to a bit of the input data that is unused in the arithmetic process in the combination circuit.

This application is a continuation application based on PCT Patent Application No. PCT/JP 2016/073431, filed Aug. 9, 2016 and amended Sep. 7, 2017 under Article 19.

### TECHNICAL FIELD

The present invention relates to an arithmetic processing device, an image processing device, and an imaging device.

### BACKGROUND ART

In an imaging device such as a still-image camera, a moving-image camera, a medical endoscope camera, or an industrial endoscope camera, various types of image processing are performed by an image processing device such as mounted system LSI. In many image processing devices mounted on an imaging device, a plurality of arithmetic processing devices configured to perform image processing are connected as image processing sections to an internal data bus. Also, in such an image processing device, for example, a storage device, for example, such as a dynamic random access memory (DRAM), configured to temporarily store image data to be subjected to image processing is connected. The storage device is connected to a data bus inside the image processing device and shared by image processing sections connected to the data bus. In such an image processing device, each image processing section performs image processing while sequentially performing reading of image data stored in the storage device or writing of processed image data in the storage device, for example, according to direct memory access (DMA) via the data bus.

Meanwhile, for example, as in the technology disclosed in Japanese Unexamined Patent Application, First Publication No. 2008-219535, a general arithmetic processing device implements a corresponding arithmetic operation according to a combination of a combination circuit including a plurality of logic circuits configured to perform predetermined arithmetic operations on input data and a flip-flop circuit configured to achieve synchronization of an arithmetic operation result output by the combination circuit. In Japanese Unexamined Patent Application, First Publication No. 2008-219535, a configuration of a synchronization circuit in which combination circuits and flip-flop circuits are alternately connected by inserting a plurality of flip-flop circuits for each predetermined arithmetic operation unit to be performed by a combination circuit is disclosed. In the technology disclosed in Japanese Unexamined Patent Application, First Publication No. 2008-219535, the same clock signal is supplied (input) to each flip-flop circuit. Then, in the technology disclosed in Japanese Unexamined Patent Application, First Publication No. 2008-219535, each flip-flop circuit temporarily stores (holds) an arithmetic operation result output by a previous-stage combination circuit and transfers (outputs) the held data of the arithmetic operation result to a subsequent-stage combination circuit every predetermined timing according to the input clock signal.

Also in each arithmetic processing device provided as the image processing section in the image processing device, as in the configuration of the synchronization circuit disclosed in Japanese Unexamined Patent Application, First Publication No. 2008-219535, a configuration of the synchronization circuit including the combining circuit and the flip-flop circuit is adopted.

Meanwhile, the size of an image to be subjected to image processing of each image processing section provided in the image processing device and the number of bits of image data differ according to an operation mode in the imaging device. More specifically, a size of an image to be captured by a solid-state imaging device provided in the imaging device and the number of bits of a pixel signal to be output are different between a still-image capturing mode for capturing still images and a moving-image capturing mode for capturing moving images in the imaging device. For example, the solid-state imaging device outputs a pixel signal of 12 bits corresponding to an image of 20 million pixels when the imaging device operates in the still-image capturing mode and a pixel signal of 10 bits corresponding to an image of 2 million pixels when the imaging device operates in the moving-image capturing mode. Thus, also in each image processing section provided in the image processing device, the size of an image to be subjected to image processing and the number of bits of image data are different between the still-image capturing mode and the moving-image capturing mode.

Also, in the image processing device, a size of an image to be subjected to image processing of each image processing section and the number of bits of image data differ according to settings of resolution and image quality of an image to be recorded in the imaging device. For example, even when the imaging device operates in the still-image capturing mode, image processing is performed on a 10-bit YC signal (a luminance color difference signal) or image processing is performed on an 8-bit YC signal in accordance with a setting of image quality.

However, in the image processing device, it is necessary to perform image processing according to each operation mode in the imaging device. Thus, in the image processing device, generally, an arithmetic processing device configured to be able to perform image processing on image data having a maximum number of bits to be handled in the imaging device is provided as an image processing section. In other words, each image processing section provided in the image processing device includes combination circuits and flip-flop circuits for a number of bits capable of coping with a maximum number of bits of image data to be handled in the imaging device.

Here, as described above, a clock signal is supplied (input) to each of the flip-flop circuits provided in each image processing section. In other words, also in the image processing device, a clock signal is supplied (input) to a flip-flop circuit corresponding to a bit that is unused in image processing in accordance with settings of an operation mode of the imaging device and resolution or image quality of an image to be recorded in the imaging device. Also, in the flip-flop circuit corresponding to a bit that is unused in such image processing, power is consumed in accordance with a supplied (input) clock signal. The consumption of power in the flip-flop circuit corresponding to the bit that is unused in image processing according to the clock signal becomes a factor that increases the power consumption of the entire image processing device.

Also, if the image processing device is advanced in performance and multi-functionality for a configuration capable of being applied to a larger number of imaging devices, the combination circuit in the image processing section becomes more complicated and the number of flip-flop circuits increases more. Thus, when the performance and the multi-functionality are higher in the image processing device, the number of flip-flop circuits corresponding to bits that are unused in image processing increases more in accordance with settings of an operation mode of the imaging device or resolution or image quality of an image to be recorded in the imaging device and a proportion of extra power consumed by these flip-flop circuits also increases more.

### SUMMARY OF INVENTION

### Solution to Problem

According to a first embodiment of the present invention, there is provided an arithmetic processing device of a pipeline configuration in which a combination of a combination circuit and a flip-flop circuit group including a plurality of flip-flop circuits corresponding to each bits of output data of the combination circuit is connected in a plurality of stages, the arithmetic processing device including: a mask processing section configured to control a mask of an operation clock signal to be supplied to each flip-flop circuit, wherein the mask processing section is configured to supply the operation clock signal to each flip-flop circuit corresponding to a bit of the input data for use in the arithmetic process in the combination circuit, and wherein the mask processing section is configured to mask the operation clock signal corresponding to a bit of the input data that is unused in the arithmetic process in the combination circuit.

According to a second aspect of the present invention, in the arithmetic processing device according to the above-described first aspect, the mask processing section may include a mask control section configured to generate a mask signal indicating whether or not to mask the operation clock signal; and a mask section configured to output an input clock signal or a predetermined fixed level signal as the operation clock signal in accordance with the mask signal, the flip-flop circuit group may include a selector corresponding to each flip-flop circuit and configured to select and output data held by the corresponding flip-flop circuit or data of a value of 0 on the basis of the mask signal corresponding to the flip-flop circuit, the selector may be configured to select the data held by the corresponding flip-flop circuit if the mask signal indicates that the operation clock signal is not masked, and the selector may be configured to select the data of the value of 0 if the mask signal indicates that the operation clock signal is masked.

According to a third aspect of the present invention, in the arithmetic processing device according to the above-described second aspect, the mask control section may be configured to generate the mask signal for each control unit in which predetermined flip-flop circuits are collectively set and the mask section may be configured to output the operation clock signal to each corresponding flip-flop circuit for each control unit.

According to a fourth aspect of the present invention, in the arithmetic processing device according to the above-described third aspect, the control unit may be configured to include the flip-flop circuits for which supply of the same operation clock signal is supplied.

According to a fifth aspect of the present invention, in the arithmetic processing device according to the above-described third aspect, the control unit may be configured to include the flip-flop circuits corresponding to the same bit of data in the flip-flop circuit groups of the each stages.

According to a sixth aspect of the present invention, in the arithmetic processing device according to the above-described third aspect, the control unit may be configured to include the flip-flop circuits corresponding to different bits of data for each flip-flop circuit group of each stage.

According to a seventh aspect of the present invention, in the arithmetic processing device according to the above-described first aspect, the mask processing section may be disposed between a position at which a clock signal is input and a branch point at which a path is branched in the path along which the clock signal input to the arithmetic processing device is supplied as the operation clock signal to each flip-flop circuit.

According to an eighth aspect of the present invention, in the arithmetic processing device according to the seventh aspect, the mask processing section may be disposed between the position at which the clock signal is input and the branch point closest to the position at which the clock signal is input.

According to a ninth aspect of the present invention, there is provided an image processing device, including: an arithmetic processing device which includes a pipeline in which a combination of a combination circuit and a flip-flop circuit group including a plurality of flip-flop circuits corresponding to each bits of output data of the combination circuit is connected in a plurality of stages and which is configured to control a mask of an operation clock signal to be supplied to each flip-flop circuit on the basis of an input instruction; and a control section configured to issue an instruction for masking the operation clock signal to be supplied to the flip-flop circuit on the basis of the number of bits of input data to be subjected to an arithmetic process to be input to the arithmetic processing device, wherein the control section is configured to instruct the arithmetic processing device to supply the operation clock signal to each flip-flop circuit corresponding to a bit of the input data for use in the arithmetic process in the combination circuit, and wherein the control section is configured to instruct the arithmetic processing device to mask the operation clock signal to be supplied to each flip-flop circuit corresponding to a bit of the input data that is unused in the arithmetic process in the combination circuit.

According to a tenth aspect of the present invention, there is provided an imaging device having a plurality of operation modes, the imaging device including: an image processing device which includes an arithmetic processing device which includes a pipeline in which a combination of a combination circuit and a flip-flop circuit group including a plurality of flip-flop circuits corresponding to each bits of output data of the combination circuit is connected in a plurality of stages and which is configured to control a mask of an operation clock signal to be supplied to each flip-flop circuit on the basis of an input instruction; and a control section configured to issue an instruction for masking the operation clock signal to be supplied to the flip-flop circuit on the basis of the number of bits of input data to be subjected to an arithmetic process input to the arithmetic processing device, wherein the control section is configured to instruct the arithmetic processing device to supply the operation clock signal to each flip-flop circuit corresponding to a bit of the input data for use in the arithmetic process in the combination circuit, wherein the control section is configured to instruct the arithmetic processing device to mask the operation clock signal to be supplied to each flip-flop circuit corresponding to a bit of the input data that is unused in the arithmetic process in the combination circuit, and wherein the number of bits of the input data differs according to each operation mode.

### BRIEF DESCRIPTION OF DRAWINGS

FIG. 1 is a block diagram showing a schematic configuration of an imaging device equipped with an image processing device including an arithmetic processing device according to a first embodiment of the present invention.

FIG. 2 is a diagram schematically showing a schematic configuration of the arithmetic processing device according to the first embodiment of the present invention.

FIG. 3 is a diagram schematically showing a method of supplying a clock signal of the arithmetic processing device according to the first embodiment of the present invention.

FIG. 4 is a diagram schematically showing a schematic configuration of the arithmetic processing device according to the first embodiment of the present invention.

FIG. 5 is a diagram schematically showing an example of a supply state of a clock signal of the arithmetic processing device according to the first embodiment of the present invention.

FIG. 6 is a diagram schematically showing another method of supplying a clock signal of the arithmetic processing device according to the first embodiment of the present invention.

FIG. 7 is a diagram schematically showing a method of supplying a clock signal of an arithmetic processing device according to a second embodiment of the present invention.

FIG. 8 is a diagram schematically showing another method of supplying a clock signal of the arithmetic processing device according to the second embodiment of the present invention.

FIG. 9 is a diagram schematically showing still another method of supplying a clock signal of the arithmetic processing device according to the second embodiment of the present invention.

FIG. 10 is a block diagram showing a schematic configuration of an imaging device equipped with an image processing device including an arithmetic processing device according to a third embodiment of the present invention.

### DESCRIPTION OF EMBODIMENTS

### First Embodiment

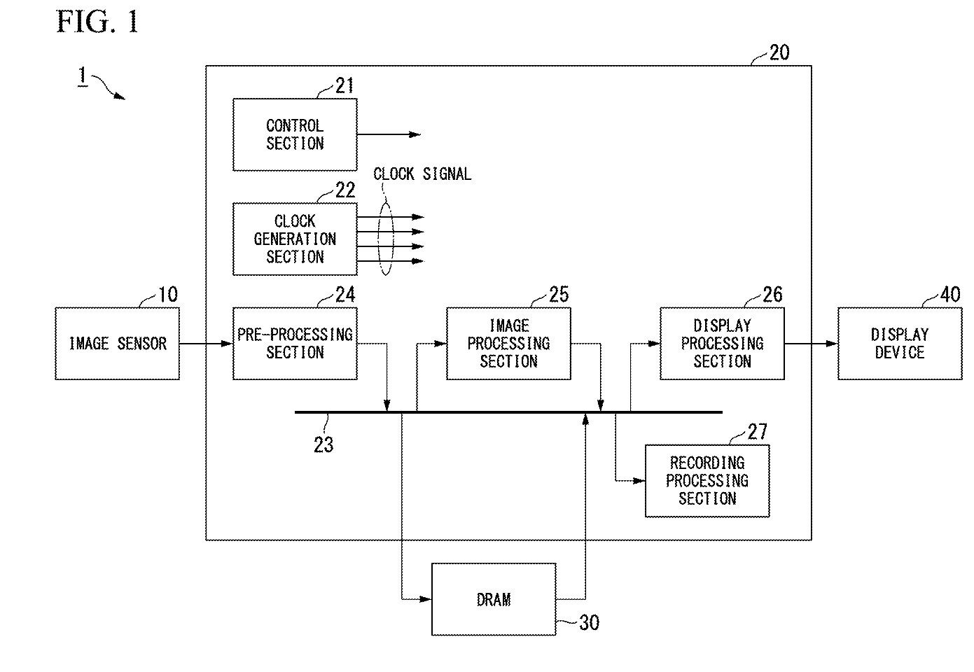

Hereinafter, embodiments of the present invention will be described with reference to the drawings. Also, in the following description, for example, a case in which an image processing device including an arithmetic processing device according to a first embodiment of the present invention is mounted on an imaging device such as a still-image camera will be described. FIG. 1 is a block diagram showing a schematic configuration of an imaging device equipped with the image processing device including the arithmetic processing device according to the first embodiment of the present invention.

The imaging device 1 shown in FIG. 1 includes an image sensor 10, an image processing device 20, a dynamic random access memory (DRAM) 30, and a display device 40. Also, the image processing device 20 includes a control section 21, a clock generation section 22, a pre-processing section 24, an image processing section 25, a display processing section 26, and a recording processing section 27. In the image processing device 20, the pre-processing section 24, the image processing section 25, the display processing section 26, and the recording processing section 27 are connected to a common bus 23 that is a common data bus.

The imaging device 1 captures an image of a subject with the image sensor 10. Then, the imaging device 1 performs various arithmetic processes on pixel signals output by the image sensor 10 with the image processing device 20 and generates an image for recording (hereinafter referred to as a “record image”) or an image for display (hereinafter referred to as a “display image”) according to an image of a subject captured by the image sensor 10 (hereinafter referred to as a “captured image”). Further, the imaging device 1 causes the display device 40 to display the display image generated by the image processing device 20. Also, the imaging device 1 causes the record image generated by the image processing device 20 to be recorded in a recording medium (not shown).

The image sensor 10 is a solid-state imaging device configured to photoelectrically convert an optical image of the subject formed by a lens (not shown) provided in the imaging device 1. For example, the image sensor 10 is a solid-state imaging device represented by a charge coupled device (CCD) image sensor and a complementary metal oxide semiconductor (CMOS) image sensor. The image sensor 10 outputs a pixel signal according to the optical image of the imaged subject to the pre-processing section 24 provided in the image processing device 20.

The display device 40 is a display device configured to display an image according to a display image output from the display processing section 26 provided in the image processing device 20. For example, the display device 40 is a display device such as a thin film transistor (TFT) liquid crystal display (LCD) or an organic electroluminescence (EL) display. Also, the display device 40 may be configured to be attachable to and detachable from the imaging device 1.

The DRAM 30 is a data storage section configured to store various data to be subjected to an arithmetic process in the image processing device 20 provided in the imaging device 1. The DRAM 30 is connected to the common bus 23 provided in the image processing device 20. The DRAM 30 stores image data of each processing step in the image processing device 20. For example, the DRAM 30 stores pixel data output by the pre-processing section 24 on the basis of the pixel signals output from the image sensor 10. Also, for example, the DRAM 30 stores data of images (a record image and a display image) generated by the image processing section 25 provided in the image processing device 20.

The image processing device 20 performs a predetermined arithmetic process (image processing) on the pixel signals output from the image sensor 10 to generate the record image or the display image. Then, the image processing device 20 causes the display device 40 to display the generated display image. Also, the image processing device 20 caused the generated record image to be recorded in the recording medium (not shown).

The control section 21 controls components provided in the image processing device 20. The control section 21 controls the entire image processing device 20 in accordance with programs and data for controlling the components. The programs and the data for controlling the components by the control section 21 may be stored in the DRAM 30 connected to the common bus 23. In other words, the control section 21 may also be connected to the common bus 23 and each component may be controlled according to a program or data acquired (or read) from the DRAM 30.

The clock generation section 22 generates a clock signal at a timing at which each component included in the image processing device 20 operates. The clock generation section 22 generates clock signals of various frequencies according to speeds at which the components operate. The clock generation section 22 supplies the generated clock signals to the corresponding components.

The pre-processing section 24 is an arithmetic processing device that generates data of an image based on pixel signals (imaging data) by performing a predetermined arithmetic process on pixel signals output from the image sensor 10. The arithmetic process to be performed by the pre-processing section 24 on the pixel signals output from the image sensor 10 is so-called pre-processing such as defect correction or shading correction. The pre-processing section 24 stores (writes) image data generated through the pre-processing (hereinafter referred to as “pre-processed image data”) in the DRAM 30 via the common bus 23.

The image processing section 25 is an arithmetic processing device configured to generate a display image or a record image according to a captured image of a subject photographed by the image sensor 10 by acquiring (reading) pre-processed image data stored in the DRAM 30 via the common bus 23 and performing a predetermined arithmetic process on the acquired pre-processed image data. The arithmetic process to be performed on the pre-processed image data by the image processing section 25 includes any of various types of image processing for display or image processing for recording such as a noise removal process, a YC conversion process, a resizing process, or a moving-image compression process such as a JPEG compression process, an MPEG compression process, or an H.264 compression process. The image processing section 25 causes data of the display image generated by performing the display image processing on the pre-processed image data (hereinafter referred to as “display image data”) to be stored (written) in the DRAM 30 via the common bus 23. Also, the image processing section 25 causes data of a record image generated by performing record image processing on the pre-processed image data (hereinafter referred to as “record image data”) to be stored (written) in the DRAM 30 via the common bus 23.

The display processing section 26 is an arithmetic processing device that acquires (reads) the display image data stored in the DRAM 30 via the common bus 23 and performs a predetermined arithmetic process on the acquired display image data. The display processing section 26 outputs the display image data subjected to the arithmetic process to the display device 40. Thereby, an image according to the display image data, i.e., a display image according to the captured image of the subject photographed by the image sensor 10, is displayed on the display device 40.

The recording processing section 27 is an arithmetic processing device that acquires (reads) the record image data stored in the DRAM 30 via the common bus 23 and performs a predetermined arithmetic process on the acquired record image data. The recording processing section 27 causes the record image data subjected to the arithmetic process to be recorded in the recording medium (not shown). Thereby, record image data, i.e., data of the record image according to the captured image of the subject photographed by the image sensor 10, is recorded on the recording medium (not shown). As examples of the recording medium in which the recording processing section 27 causes the record image data to be recorded, there are recording media with various configurations such as an SD memory card and Compact Flash (CF (registered trademark)).

According to such a configuration, the imaging device 1 generates a display image according to the captured image of the subject photographed by the image sensor 10 through the image processing device 20 including various arithmetic processing devices and causes the display device 40 to display the generated display image. Also, the imaging device 1 generates a record image corresponding to the captured image of the subject photographed by the image sensor 10 through the image processing device 20 including various arithmetic processing devices and causes the generated record image to be recorded in the recording medium (not shown).

Next, the arithmetic processing device configured in the image processing device 20 provided in the imaging device 1 will be described. In the following description, the pre-processing section 24 will be described as a representative of arithmetic processing devices according to the first embodiment of the present invention.

Even when the arithmetic processing devices according to the first embodiment of the present invention are the image processing section 25, the display processing section 26, and the recording processing section 27, configurations and operation thereof may be similar to those of the pre-processing section 24 to be described below.

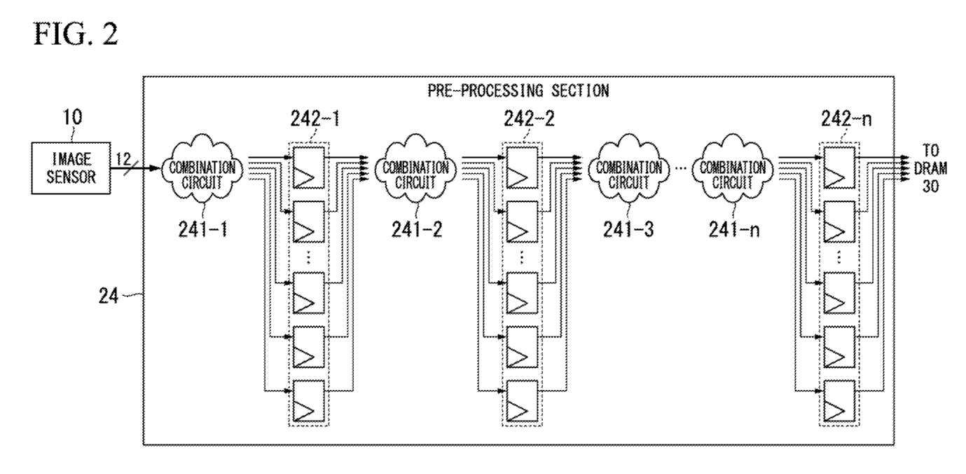

FIG. 2 is a diagram schematically showing a schematic configuration of the pre-processing section 24 that is an arithmetic processing device according to the first embodiment of the present invention. In FIG. 2, a flow of data of an image to be processed in the pre-processing section 24 is schematically shown.

As described above, in the imaging device 1, a pixel signal output by the image sensor 10 is input to the pre-processing section 24 provided in the image processing device 20. In other words, in the imaging device 1, the pixel signal output by the image sensor 10 is input to the pre-processing section 24 as data to be subjected to an arithmetic process. In FIG. 2, an example when a pixel signal represented by 12-bit data is output to the pre-processing section 24 at a signal level of each pixel in the image of the subject photographed by the image sensor 10 is shown.

The pre-processing section 24 includes combinations of a plurality of combination circuits 241, each of which performs a predetermined arithmetic process on an input pixel signal, and flip-flop circuit groups 242 corresponding to the combination circuits 241. In FIG. 2, an example of the pre-processing section 24 having a configuration in which a combination of the combination circuit 241 and the flip-flop circuit group 242 is connected in n stages (n is a natural number or a positive integer), i.e., a so-called pipeline configuration, is shown. Also, in FIG. 2, a sequential stage number of the combination circuit 241 or the flip-flop circuit group 242 is attached after “-” following the reference sign of the combination circuit 241 or the flip-flop circuit group 242 of each stage. More specifically, the combination circuit 241 of a 1^{st} stage is denoted as a “combination circuit 241-1” by attaching “1” indicating the 1^{st} stage after “-” following the reference sign thereof. Also, the flip-flop circuit group 242 of the 1^{st} stage is denoted as a “flip-flop circuit group 242-1” by attaching “1” indicating the 1^{st} stage after “-” following the reference sign thereof. The combination circuit 241 of an n^{th} stage is denoted as a “combination circuit 241-n” by attaching “n” indicating the nth stage after “-” following the reference sign thereof. Also, the flip-flop circuit group 242 of the n^{th} stage is denoted as “a flip-flop circuit group 242-n” by attaching “n” indicating the n^{th} stage after “-” following the reference sign thereof.

Each combination circuit 241 includes a plurality of logic circuits configured to perform predetermined logical operations. The logic circuit is, for example, a circuit configured to perform a logical operation such as an INV circuit, an OR circuit, an AND circuit, a NOR circuit, or a NAND circuit.

Each flip-flop circuit group 242 includes a plurality of flip-flop circuits for establishing data of an arithmetic operation result output by the corresponding combination circuit 241 by achieving synchronization at a predetermined timing. The flip-flop circuit temporarily stores (holds) data of a corresponding bit in the arithmetic operation result output by the combination circuit 241 at a predetermined timing. Each flip-flop circuit group 242 includes flip-flop circuits for a number of bits of data of the arithmetic operation result output by the combination circuit 241. In other words, each flip-flop circuit group 242 temporarily stores (holds) data of the arithmetic operation result output by the combination circuit 241 for each bit. In an example of the configuration of the pre-processing section 24 shown in FIG. 2, each flip-flop circuit group 242 includes flip-flop circuits for 12 bits, i.e., 12 flip-flop circuits.

In the pre-processing section 24, the combination circuits 241 sequentially performs arithmetic processes on a pixel signal of 12 bits output from the image sensor 10, and the combination circuit 241-n of the n^{th} stage that is the last stage outputs final 12-bit data of an arithmetic operation result obtained by performing an arithmetic process as pre-processed image data to the DRAM 30 via the common bus 23. In other words, the pre-processing section 24 is an arithmetic processing device in which the n stage combination circuits 241 perform pipeline processing in order.

More specifically, the combination circuit 241-1 of the 1^{st} stage first performs an arithmetic process on 12-bit data of the pixel signal output from the image sensor 10 to output 12-bit data of the arithmetic operation result. Then, the flip-flop circuit group 242-1 of the 1^{st} stage temporarily stores (holds) the 12-bit data of the arithmetic operation result output from the combination circuit 241-1 in the flip-flop circuits corresponding to the bits and outputs the temporarily stored (held) bit data to the combination circuit 241-2 of the subsequent stage (a 2^{nd} stage).

Thereafter, the combination circuit 241-2 of the 2^{nd} stage generates 12-bit data of an arithmetic operation result by further performing an arithmetic process on the 12-bit data of the arithmetic operation result output from the flip-flop circuit group 242-1 of the previous stage (the 1^{st} stage). Then, the flip-flop circuit group 242-2 of the 2^{nd} stage temporarily stores (holds) the 12-bit data of the arithmetic operation result output from the combination circuit 241-2 in the flip-flop circuits corresponding to the bits and outputs the temporarily stored (held) bit data to the combination circuit 241-3 of the subsequent stage (a 3^{rd} stage).

Thereafter, the 12-bit data of the arithmetic operation result for which each combination circuit 241 has performed the arithmetic operation is temporarily stored (held) by the flip-flop circuits constituting the corresponding flip-flop circuit group 242, and the temporarily stored (held) bit data is output to the combination circuit 241 of the subsequent stage.

Then, the combination circuit 241-n of the last stage (the n^{th} stage) outputs 12-bit data of the arithmetic operation result by further performing an arithmetic process on the 12-bit data of the arithmetic operation result output from a flip-flop circuit group 242-(n-1) of a previous stage (an (n-1)^{th} stage). The flip-flop circuit group 242-n of the last stage (the n^{th} stage) temporarily stores (holds) the corresponding 12-bit data of the arithmetic operation result output from the combination circuit 241-n in the flip-flop circuits corresponding to the bits and outputs the temporarily stored (held) bit data as pre-processed image data to the DRAM 30 via the common bus 23.

According to such a configuration and operation, the pre-processing section 24 causes data of an arithmetic operation result obtained by performing an arithmetic process on a 12-bit pixel signal output from the image sensor 10 to be sequentially established (temporarily stored (held)) while achieving synchronization through the flip-flop circuits for the corresponding bits and causes 12-bit data of the arithmetic operation result obtained by performing the final arithmetic process to be stored (written) as 12-bit pre-processed image data in the DRAM 30. Also, in the pre-processing section 24, a timing at which each flip-flop circuit temporarily stores (holds) the data of the corresponding bit, i.e., a timing for achieving and establishing synchronization of data of an arithmetic operation result output by the corresponding combination circuit 241, is a timing based on a clock signal output from the clock generation section 22.

The pre-processing section 24 controls the supply of the clock signal to each flip-flop circuit in a predetermined control unit. More specifically, the pre-processing section 24 controls the supply of the clock signal for each flip-flop circuit by combining flip-flop circuits constituting each flip-flop circuit group 242 provided in the pre-processing section 24 on the basis of a predetermined condition and designating a plurality of flip-flop circuits combined here as one control unit.

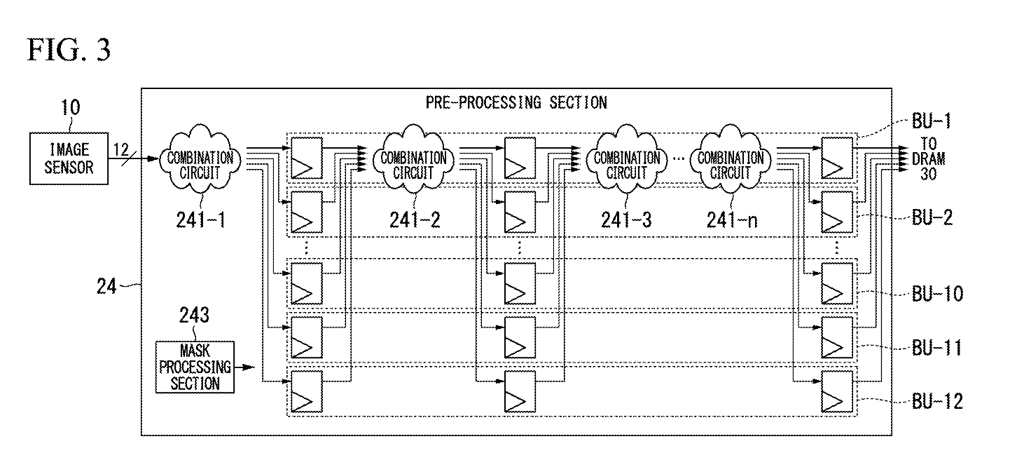

Next, a method of supplying a clock signal to each flip-flop circuit in the pre-processing section 24 will be described. FIG. 3 is a diagram schematically showing a method of supplying a clock signal of the pre-processing section 24 that is an arithmetic processing device according to the first embodiment of the present invention. In FIG. 3, the pre-processing section 24 having a configuration in which flip-flop circuits corresponding to the same bit in the flip-flop circuit groups 242 provided in the pre-processing section 24 are combined and the supply (input) of the clock signal is controlled is shown. In other words, the pre-processing section 24 shown in FIG. 3 is an arithmetic processing device having a configuration in which a plurality of flip-flop circuits corresponding to the same bit constituting the flip-flop circuit groups 242 are set as one control unit for controlling the supply (input) of the clock signal.

More specifically, in the pre-processing section 24, flip-flop circuits for a 1^{st} bit constituting the flip-flop circuit groups 242 provided in the pre-processing section 24 are collectively set as a bit control unit BU-1. Also, likewise, in the pre-processing section 24, flip-flop circuits for a 2^{nd} bit are collectively set as a bit control unit BU-2. Likewise, in the pre-processing section 24, flip-flop circuits for a 10^{th} bit are collectively set as a bit control unit BU-10, flip-flop circuits for an 11^{th} bit are collectively set as a bit control unit BU-11, and flip-flop circuits for a 12^{th} bit are collectively set as a bit control unit BU-12.

Then, the pre-processing section 24 controls the supply (input) of the clock signal for achieving and establishing synchronization of the arithmetic operation result output by the corresponding combination circuit 241 for each set bit control unit. In FIG. 3, a mask processing section 243 for controlling the supply (input) of the clock signal for each bit control unit is briefly shown.

On the basis of control (an instruction) from the control section 21 provided in the image processing device 20, the mask processing section 243 controls the supply (input) of the clock signal to a flip-flop circuit for a bit constituting each flip-flop circuit group 242 provided in the pre-processing section 24 for each bit control unit. Here, when each arithmetic processing device provided in the image processing device 20 performs an arithmetic process, the control section 21 performs control so that the arithmetic process is performed on data having a number of valid bits. The number of valid bits is the number of bits necessary for performing the arithmetic process on a maximum number of bits predetermined for each operation mode of the imaging device 1.

For example, if the imaging device 1 operates in the still-image capturing mode, the image sensor 10 outputs a 12-bit pixel signal in which a signal level of each pixel is indicated by 12-bit data. Thus, the control section 21 performs control so that each arithmetic processing device performs an arithmetic process on the 12-bit pixel signal. More specifically, the control section 21 performs control (issues an instruction) so that a clock signal is supplied (input) to all the bit control units BU-1 to BU-12 in the pre-processing section 24, i.e., performs control (issues an instruction) so that a clock signal is supplied (input) to all flip-flop circuits provided in the pre-processing section 24, and performs control so that all bits of data of an arithmetic operation result output by each combination circuit 241 provided in the pre-processing section 24 are synchronized and established as valid data.

Also, for example, if the imaging device 1 operates in the moving-image capturing mode, the image sensor 10 outputs a 10-bit pixel signal in which the signal level of each pixel is indicated by 10-bit data. Thus, the control section 21 performs control so that each arithmetic processing device performs an arithmetic process on the 10-bit pixel signal. In other words, the control section 21 performs control so that an arithmetic process is performed on 10-bit data within the 12-bit data on which each arithmetic processing device is able to perform an arithmetic process. More specifically, the control section 21 performs control (issues an instruction) so that a clock signal is supplied (input) to the bit control units BU-1 to BU-10 in the pre-processing section 24, i.e., performs control (issues an instruction) so that a clock signal is supplied (input) to flip-flop circuits for 1^{st} to 10^{th} bits provided in the pre-processing section 24, and performs control so that corresponding bits of data of an arithmetic operation result output by each combination circuit 241 provided in the pre-processing section 24 are synchronized and established as valid data. Also, the control section 21 performs control (issues an instruction) so that no lock signal is supplied (input) to the bit control units BU-11 and BU-12, i.e., flip-flop circuits for 11^{th} and 12^{th} bits constituting each flip-flop circuit group 242, in the pre-processing section 24. Thereby, the flip-flop circuits belonging to the bit control unit BU-11 and the bit control unit BU-12 do not perform an operation of establishing data of corresponding bits of an arithmetic operation result output by each combination circuit 241 provided in the pre-processing section 24, i.e., stop an operation of temporarily storing (holding) the data of the corresponding bits.

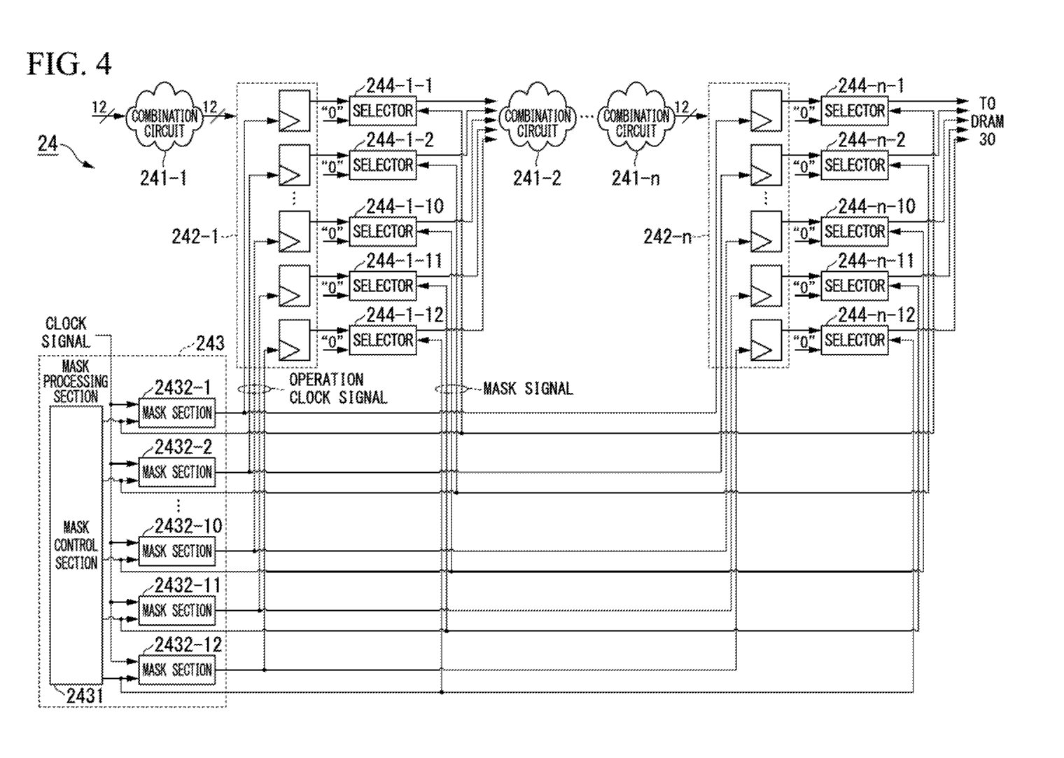

Next, a configuration for supplying a clock signal to each flip-flop circuit in the pre-processing section 24 will be described. FIG. 4 is a diagram schematically showing a schematic configuration of a pre-processing section 24 that is an arithmetic processing device according to the first embodiment of the present invention. In FIG. 4, the pre-processing section 24 configured to control the supply (input) of a clock signal by designating the bit control unit BU as shown in FIG. 3 as a control unit is shown. In other words, in FIG. 4, the pre-processing section 24 configured to supply (input) a clock signal for achieving and establishing the synchronization of an arithmetic operation result output by the corresponding combination circuit 241 to the flip-flop circuits belonging to the same bit control unit BU constituting the flip-flop circuit groups 242 provided in the pre-processing section 24 is shown.

Also, in FIG. 4, only configurations of the combination circuit 241-1 and the flip-flop circuit group 242-1 in an initial stage (a 1^{st} stage) to which data of a 12-bit pixel signal output from the image sensor 10 is input and the combination circuit 241-n and the flip-flop circuit group 242-n in a last stage (an n^{th} stage) from which pre-processed image data is output to the DRAM 30 within the configurations of the pre-processing section 24 shown in FIG. 2 and FIG. 3 are shown. A configuration in which a clock signal is supplied (input) to each flip-flop circuit constituting the flip-flop circuit group 242 of another stage is similar to a configuration in which a clock signal is supplied (input) to each flip-flop circuit constituting the flip-flop circuit group 242-1 and the flip-flop circuit group 242-n to be described blow.

The pre-processing section 24 includes the mask processing section 243 and a plurality of selectors 244. Also, the mask processing section 243 includes a mask control section 2431 and a plurality of mask sections 2432.

On the basis of control (an instruction) from the control section 21 provided in the image processing device 20, the mask processing section 243 controls the supply (input) of the clock signal to the flip-flop circuit of each bit constituting each flip-flop circuit group 242 provided in the pre-processing section 24. Also, the mask processing section 243 controls the selector 244 corresponding to the flip-flop circuit for each bit and switches data to be output to the combination circuit 241 of a subsequent stage by each flip-flop circuit in accordance with a control state of the supply (input) of the clock signal to each flip-flop circuit.

The mask control section 2431 controls whether or not to supply (input) a clock signal output from the clock generation section 22 provided in the image processing device 20 to flip-flop circuits constituting each flip-flop circuit group 242 on the basis of control (an instruction) from the control section 21 provided in the image processing device 20. In other words, the mask control section 2431 controls whether or not to mask the clock signal to be supplied (input) to each flip-flop circuit. More specifically, the mask control section 2431 generates a mask signal for controlling the mask of the clock signal for each bit control unit BU on the basis of control (an instruction) from the control section 21 provided in the image processing device 20. Then, the mask control section 2431 outputs the generated mask signal for each bit control unit BU to the corresponding mask section 2432 and the corresponding selector 244.

Each of the mask sections 2432 supplies (inputs) a clock signal (hereinafter referred to as an “operation clock signal”) to each flip-flop circuit belonging to the corresponding bit control unit BU. In the mask processing section 243 shown in FIG. 4, a configuration including 12 mask sections 2432 corresponding to bits of 12-bit data on which the pre-processing section 24 performs an arithmetic process is shown. Also, in FIG. 4, a numeral indicating the corresponding bit control unit BU is attached after “-” following the reference sign of each mask section 2432. More specifically, the mask section 2432 corresponding to the bit control unit BU-1 for the first bit is denoted as a “mask section 2432-1” by attaching “1” indicating correspondence to the bit control unit BU-1 after “-” following the reference sign thereof. Also, the mask section 2432 corresponding to the bit control unit BU-10 for the tenth bit is denoted as a “mask section 2432-10” by attaching “10” indicating correspondence to the bit control unit BU-10 after “-” following the reference sign thereof.

When an operation clock signal is supplied (input) to each flip-flop circuit belonging to the corresponding bit control unit BU, each mask section 2432 masks an operation clock signal to be supplied (input) in accordance with a mask signal of the corresponding bit control unit BU output from the mask control section 2431.

More specifically, if the mask signal of the corresponding bit control unit BU output from the mask control section 2431 indicates that a clock signal is not masked, each mask section 2432 outputs a clock signal output from the clock generation section 22 as the operation clock signal to each flip-flop circuit belonging to the corresponding bit control unit BU. Thereby, the flip-flop circuit to which the operation clock signal is input causes data of an arithmetic operation result to be established by temporarily storing (holding) the data of the arithmetic operation result output by the corresponding combination circuit 241 at a timing of the input operation clock signal.

On the other hand, if the mask signal of the corresponding bit control unit BU output from the mask control section 2431 indicates that the clock signal is masked, the mask section 2432 masks the clock signal output from the clock generation section 22 and outputs an operation clock signal of a predetermined signal level to each flip-flop circuit belonging to the corresponding bit control unit BU. Here, the signal level of the operation clock signal output by the mask section 2432 when the clock signal is masked, is a signal level at which an operation in which each flip-flop circuit of the corresponding bit control unit BU temporarily stores (holds) the data is not performed. For example, if each flip-flop circuit is a flip-flop circuit configured to perform an operation of temporarily storing (holding) data input at a rising timing of the operation clock signal, the mask section 2432 outputs an operation clock signal in which the signal level is fixed to a “Low” level, i.e., in which there is no rising timing, to each flip-flop circuit belonging to the corresponding bit control unit BU.

Each of the selectors 244 selects data to be output in accordance with the mask signal output from the mask control section 2431 provided in the mask processing section 243. In the pre-processing section 24 shown in FIG. 4, a configuration including 12 selectors 244 corresponding to bits of 12-bit data output by the flip-flop circuit group 242 for each flip-flop circuit group 242 is shown. Also, in FIG. 4, a numeral indicating the corresponding bit control unit BU is attached after “-” following the reference sign of each selector 244. More specifically, the selector 244-1 corresponding to the bit control unit BU-1 for the 1^{st} bit in the flip-flop circuit group 242-1 of the 1^{st} stage is denoted as a “selector 244-1-1” by attaching “1” indicating correspondence to the bit control unit BU-1 after “-” following the reference sign thereof. Also, the selector 244-1 corresponding to the bit control unit BU-10 for the 10^{th} bit in the flip-flop circuit group 242-1 of the 1^{st} stage is denoted as a “selector 244-1-10” by attaching “10” indicating correspondence to the bit control unit BU-10 after “-” following the reference sign thereof. Also, the selector 244-n corresponding to the bit control unit BU-1 for the 1^{st} bit in the flip-flop circuit group 242-n of the n^{th} stage is denoted as a “selector 244-n-1” by attaching “1” indicating correspondence to the bit control unit BU-1 after “-” following the reference sign thereof. Also, the selector 244-n corresponding to the bit control unit BU-10 for the 10^{th} bit in the flip-flop circuit group 242-n of the n^{th} stage is denoted as a “selector 244-n-10” by attaching “10” indicating correspondence to the bit control unit BU-10 after “-” following the reference sign thereof.

If the mask signal of the corresponding bit control unit BU output from the mask control section 2431 provided in the mask processing section 243 indicates that the clock signal is not masked, each selector 244 selects and outputs data output from the corresponding flip-flop circuit. Thereby, data temporarily stored (held) by the corresponding flip-flop circuit is output to the combination circuit 241 of the subsequent stage or the DRAM 30.

On the other hand, if the mask signal of the corresponding bit control unit BU output from the mask control section 2431 provided in the mask processing section 243 indicates that the clock signal is masked, the selector 244 outputs data of a predetermined value (e.g., “0”) without selecting data output from the corresponding flip-flop circuit. Thereby, the data of the predetermined value (e.g., “0”) is output to the combination circuit 241 of the subsequent stage or the DRAM 30.

According to such a configuration, the pre-processing section 24 causes only a flip-flop circuit corresponding to a pixel signal of a valid bit output from the image sensor 10 to be operated. In other words, the pre-processing section 24 causes the operation of a flip-flop circuit corresponding to a pixel signal of an invalid bit output from the image sensor 10 to be stopped. Thereby, in the pre-processing section 24, it is possible to reduce power to be consumed by supplying (inputting) an operation clock signal to a flip-flop circuit corresponding to data of an invalid bit when the arithmetic process is performed. In other words, in the pre-processing section 24, power to be consumed in a clock tree of an operation clock signal to be supplied (input) to the flip-flop circuit corresponding to a bit of data that is unused in the arithmetic process in pipeline processing is able to be reduced in the bit control unit BU.

For example, if the imaging device 1 operates in the still-image capturing mode, because the image sensor 10 outputs a 12-bit pixel signal, the mask processing section 243 causes all (12) flip-flop circuits provided in each flip-flop circuit group 242 to be operated by supplying (inputting) the operation clock signal thereto. In other words, if the imaging device 1 operates in the still-image capturing mode, the mask processing section 243 causes the flip-flop circuits belonging to each of the bit control units BU-1 to BU-12 to be operated.

Also, for example, if the imaging device 1 operates in the moving-image capturing mode, because the image sensor 10 outputs a 10-bit pixel signal, the mask processing section 243 causes flip-flop circuits for 10 bits within all (12) flip-flop circuits provided in each flip-flop circuit group 242 to be operated by supplying (inputting) the operation clock signal thereto. In other words, if the imaging device 1 operates in the moving-image capturing mode, the mask processing section 243 causes operations of flip-flop circuits for two bits (e.g., flip-flop circuits belonging to the bit control unit BU-11 and the bit control unit BU-12) to be stopped. Thereby, the pre-processing section 24 is able to reduce power to be consumed by flip-flop circuits for two bits for which an operation is stopped.

Also, the clock tree is a clock tree in which a path until the operation clock signal is input from a position at which a clock signal output from the clock generation section 22 is input to the pre-processing section 24, i.e., a clock input terminal in the pre-processing section 24, to the flip-flop circuit constituting each flip-flop circuit group 242 is represented in the form of a tree. As shown in FIG. 4, in the pre-processing section 24, there are a plurality of branch points in a path along which the clock signal output from the clock generation section 22 is supplied (input) as the operation clock signal to each flip-flop circuit via the mask section 2432. Accordingly, in the clock tree of the pre-processing section 24, a path along which the operation clock signal is supplied (input) to each flip-flop circuit and the branch points thereof are represented.

The clock tree is used in a design for adjusting (aligning) the timing of the operation clock signal to be supplied (input) to each flip-flop circuit, for example, when the image processing device 20 or the pre-processing section 24 is implemented as system LSI. At this time, a buffer circuit is generally used as a circuit element for adjusting (aligning) the timing of the operation clock signal, i.e., a circuit element for actually delivering the operation clock signal to each flip-flop circuit. In other words, when the image processing device 20 or the pre-processing section 24 is implemented as system LSI, the buffer circuit is appropriately inserted into (disposed in) a path along which an operation clock signal is supplied (input) from a clock input terminal of the pre-processing section 24 to the flip-flop circuits belonging to each flip-flop circuit group 242, i.e., a so-called clock signal line.

Also, the number of buffer circuits to be inserted into the clock signal line or a position where the buffer circuit is disposed in the clock signal line is determined in consideration of a delay time of the operation clock signal to be supplied (input) to each flip-flop circuit, driving capability of an operation clock signal in the buffer circuit, i.e., so-called fan-out in the buffer circuit, or the like. For example, in the pre-processing section 24 shown in FIG. 4, a buffer circuit is disposed immediately before a branch point on a path along which the mask section 2432 supplies (inputs) an operation clock signal to each corresponding flip-flop circuit. Each buffer circuit serves to increase an amount of current to be consumed in the corresponding flip-flop circuit. Thus, each buffer circuit also consumes power.

Accordingly, the pre-processing section 24 is able to also reduce power to be consumed by a buffer circuit for supplying (inputting) the operation clock signal to the flip-flop circuit corresponding to data of an invalid bit when an arithmetic process is performed by causing an operation of a flip-flop circuit corresponding to a pixel signal of an invalid bit output from the image sensor 10 to be stopped. In other words, the pre-processing section 24 is able to reduce power to be consumed in all circuit elements for supplying (inputting) the operation clock signal to the flip-flop circuit corresponding to a data bit that is unused in the arithmetic process in the pipeline processing in a bit control unit BU.

Also, when the number of flip-flop circuit groups 242 increases in the pre-processing section 24, the number of paths for supplying (inputting) the operation clock signal to the flip-flop circuits belonging to each flip-flop circuit group 242 increases. In other words, the number of branch points in the clock tree increases. In this case, the number of buffer circuits to be inserted into (disposed in) the clock signal line also increases. When the number of buffer circuits to be inserted into (disposed in) the clock signal line increases, in particular, when a frequency of the operation clock signal is high, a proportion of an influence of a delay time of the operation clock signal in each buffer circuit on the operation of the pre-processing section 24 also increases. Thus, a case in which a buffer circuit for adjusting a timing is further inserted into (disposed in) a path for supplying (inputting) the operation clock signal to take the balance of the operation clock signal to be supplied (input) to each flip-flop circuit in the pre-processing section 24 is also conceived. Accordingly, the pre-processing section 24 is able to more significantly obtain an effect of reducing power to be consumed by stopping the operation of the flip-flop circuit as the number of flip-flop circuit groups 242 increases.

Also, in the pre-processing section 24 shown in FIG. 4, a case in which the mask processing section 243 is disposed at a position between the flip-flop circuit group 242-1 of the 1^{st} stage and a position where the clock signal output from the clock generation section 22 is input to the pre-processing section 24 (the clock input terminal in the pre-processing section 24) is shown. However, the position where the mask processing section 243 is disposed is not limited to the position shown in FIG. 4. For example, the mask processing section 243 is disposed at a position close to any flip-flop circuit group 242 between the flip-flop circuit group 242-1 of the 1^{st} stage and the flip-flop circuit group 242-n of the n^{th} stage. However, it is more preferable to perform control of whether or not to mask the operation clock signal to be supplied (input) to the flip-flop circuits belonging to each flip-flop circuit group 242 at a root of the clock tree, i.e., a position closer to a position where the clock signal output from the clock generation section 22 is input to the pre-processing section 24 (the clock input terminal in the pre-processing section 24) as shown in FIG. 4. This is because it is possible to more significantly obtain an effect of reducing power to be consumed by buffer circuits including a buffer circuit inserted into (disposed in) the clock signal line obtained as described above.

More specifically, as described above, for example, if the imaging device 1 operates in the moving-image capturing mode, the mask processing section 243 causes the operations of the flip-flop circuits for two bits to be stopped by masking an operation clock signal to be supplied (input) to the flip-flop circuits for the two bits within all (12) flip-flop circuits provided in each flip-flop circuit group 242. In other words, the mask processing section 243 causes the operations of flip-flop circuits for two bits belonging to the bit control unit BU-11 and the bit control unit BU-12 to be stopped through the mask section 2432-11 and the mask section 2432-12. At this time, as shown in FIG. 4, because the mask processing section 243 is disposed at a position of the root of the clock tree, an operation including a buffer circuit inserted into (disposed in) a clock signal line for delivering an operation clock signal to the flip-flop circuits for the two bits is stopped in addition to the flip-flop circuits for the two bits for which operations have been stopped. Thereby, the pre-processing section 24 is able to reduce power to be consumed by the flip-flop circuits for the two bits and the buffer circuit for which an operation has been stopped. In this manner, it is possible to reduce power to be consumed by all components connected to the clock signal line by disposing the mask processing section 243 at a position closer to the clock input terminal in the pre-processing section 24 and controlling a mask of the operation clock signal.

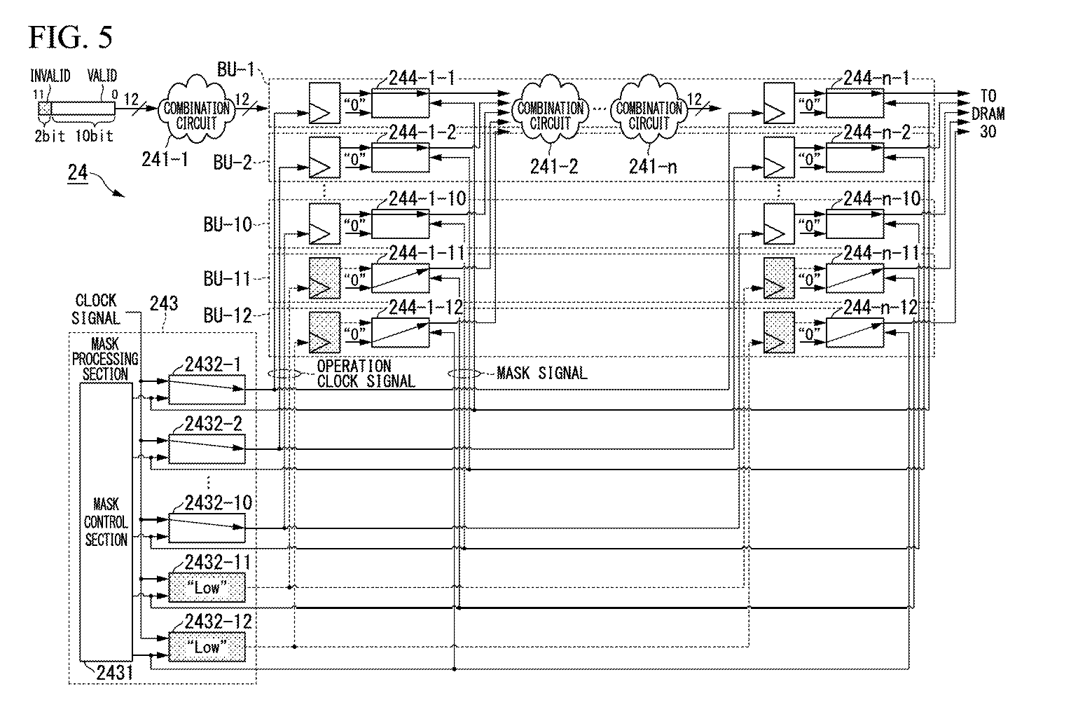

Here, an example in which an operation clock signal is supplied (input) to each flip-flop circuit group 242 provided in the pre-processing section 24 when the imaging device 1 operates in the moving-image capturing mode will be described. FIG. 5 is a diagram schematically showing an example of a supply state of a clock signal (an operation clock signal) of the pre-processing section 24 that is an arithmetic processing device according to the first embodiment of the present invention.

In FIG. 5, an example in which the image sensor 10 outputs a 12-bit pixel signal that is a pixel signal in which 10 bits from a 0^{th} bit to a 9^{th} bit are valid and is a pixel signal in which a 10^{th} bit and a 11^{th} bit are invalid is shown. Also, in FIG. 5, an example of a supply state of an operation clock signal when a 0^{th}-bit pixel signal is assigned to a bit control unit BU-1 in which flip-flop circuits for the 1^{st} bit constituting the flip-flop circuit groups 242 provided in the pre-processing section 24 are collectively set and 1^{st}- to 11^{th}-bit pixel signals are subsequently sequentially assigned to the bit control units BU-2 to BU-12 is shown.

If each bit of the pixel signal is assigned to each bit control unit BU as described above, the mask processing section 243 causes flip-flop circuits belonging to the bit control units BU-1 to BU-10 to be operated and causes operations of flip-flop circuits belonging to the bit control units BU-11 and BU-12 to be stopped on the basis of control (an instruction) from the control section 21 provided in the image processing device 20.

More specifically, the mask control section 2431 outputs a mask signal indicating that the clock signal is not masked to mask sections 2432-1 to 2432-10, selectors 244-1-1 to 244-1-10, and selectors 244-n-1 to 244-n-10 corresponding to the bit control units BU-1 to BU-10. Also, the mask control section 2431 outputs a mask signal indicating that the clock signal is masked to mask sections 2432-11 and 2432-12, selectors 244-1-11 and 244-1-12, and selectors 244-n-11 and 244-n-12 corresponding to the bit control unit BU-11 and the bit control unit BU-12.

Thereby, the mask sections 2432-1 to 2432-10 output clock signals output from the clock generation section 22 as operation clock signals to the flip-flop circuits belonging to the bit control units BU-1 to BU-10. The flip-flop circuits belonging to the bit control units BU-1 to BU-10 perform an operation of temporarily storing (holding) and establishing data of an arithmetic operation result output by a corresponding combination circuit 241 in accordance with a timing of the input operation clock signal. Also, the mask sections 2432-11 and 2432-12 output an operation clock signal of a signal level fixed to a predetermined “Low” level to the flip-flop circuits of the bit control units BU-11 and BU-12. Because an operation clock signal input to each of the flip-flop circuits belonging to the bit control units BU-11 and BU-12 is an operation clock signal fixed to a “Low” level, an operation of establishing data of an arithmetic operation result output by the corresponding combination circuit 241 is not performed (an operation of temporarily storing (holding) the data of the arithmetic operation result is stopped). Thereby, in the pre-processing section 24, power to be consumed by the flip-flop circuits belonging to the bit control units BU-11 and BU-12 is reduced.

Also, each of the selectors 244-1-1 to 244-1-10 and the selectors 244-n-1 to 244-n-10 selects and outputs data output from the flip-flop circuit provided in the corresponding flip-flop circuit group 242. Thereby, the data temporarily stored (held) by the flip-flop circuit corresponding to each of the selectors 244-1-1 to 244-1-10 is output to the combination circuit 241-2 of the subsequent stage and the data temporarily stored (held) by the flip-flop circuit corresponding to each of the selectors 244-n-1 to 244-n-10 is output to the DRAM 30. Also, each of the selector 244-1-11, the selector 244-1-12, the selector 244-n-11, and the selector 244-n-12 outputs data having a predetermined value=“0”. Thereby, the data of the value=“0” output by each of the selector 244-1-11 and the selector 244-1-12 is output to the combination circuit 241-2 of the subsequent stage and a logic circuit for performing a logical operation on 11^{th}- and 12^{th}-bit data in the combination circuit 241-2 of the subsequent stage becomes stable without causing malfunction. In other words, the combination circuit 241-2 is in a state in which the arithmetic process is not performed on the 11^{th}- and 12^{th}-bit data. Also, the data of the value=“0” output by each of the selectors 244-n-1 to 244-n-10 is output to the DRAM 30.

Thereby, the pre-processing section 24 stores (writes) pre-processed image data obtained by performing an arithmetic process on a pixel signal of 10 valid bits from the 0^{th} bit to the 9^{th} bit output by the image sensor 10 in the DRAM 30 via the common bus 23.

According to such a configuration and operation, the pre-processing section 24 is able to stop an arithmetic process on invalid bit data and reduce the consumption of power corresponding to power consumption when an operation clock signal is supplied to the flip-flop circuit corresponding to a bit that is unused in the arithmetic process.

Also, in the example shown in FIG. 5, a case in which the bit control units BU are sequentially assigned from the bit control unit BU-1 with respect to the 12-bit pixel signal that is a pixel signal in which 10 bits from a 0^{th} bit to a 9^{th} bit are valid and is a pixel signal in which a 10^{th} bit and an 11^{th} bit are invalid has been described. However, recent image sensors also include an image sensor in which pixel signals are output as a serial signal of a differential transmission scheme, for example, such as a low voltage differential signaling (LVDS) scheme. Thus, valid bits in the pixel signals output by the image sensor are not necessarily 0^{th} to 9^{th} bits as in the example shown in FIG. 5. For example, the 1^{st} to 10^{th} bits may be valid pixel signal bits or the 2^{nd} to 11^{th} bits may be valid pixel signal bits. Accordingly, the bit control unit BU assigned to each bit of the pixel signal in the pre-processing section 24 is also not limited to an assignment method as shown in the example shown in FIG. 5.

According to the present first embodiment, there is provided an arithmetic processing device (e.g., the pre-processing section 24) of a pipeline configuration in which a combination of a combination circuit (the combination circuit 241) and a flip-flop circuit group (the flip-flop circuit group 242) including a plurality of flip-flop circuits corresponding to each bits of output data of the combination circuit 241 is connected in a plurality of stages, the arithmetic processing device (e.g., the pre-processing section 24) including: a mask processing section (the mask processing section 243) configured to control a mask of an operation clock signal to be supplied to each flip-flop circuit, wherein the mask processing section 243 is configured to control the mask of the operation clock signal to be supplied to each flip-flop circuit on the basis of a bit for use in an arithmetic process in input data (a pixel signal) to be input to the combination circuit 241.

Also, according to the present first embodiment, the arithmetic processing device (e.g., the pre-processing section 24) is configured in which the mask processing section 243 is configured to supply the operation clock signal to each flip-flop circuit corresponding to a bit of the input data (e.g., the pixel signal) for use in the arithmetic process in the combination circuit 241, and the mask processing section 243 is configured to mask the operation clock signal corresponding to a bit of the input data (e.g., the pixel signal) that is unused in the arithmetic process in the combination circuit 241.

Also, according to the present first embodiment, the arithmetic processing device (e.g., the pre-processing section 24) is configured in which the mask processing section 243 includes a mask control section (the mask control section 2431) configured to generate a mask signal indicating whether or not to mask the operation clock signal; and a mask section (the mask section 2432) configured to output an input clock signal or a predetermined fixed level (e.g., “Low” level) signal as the operation clock signal in accordance with the mask signal, wherein the flip-flop circuit group 242 includes a selector (the selector 244) corresponding to each flip-flop circuit and configured to select and output data held by the corresponding flip-flop circuit or data of a value of 0 on the basis of the mask signal corresponding to the flip-flop circuit, and wherein the selector 244 is configured to select the data held by the corresponding flip-flop circuit if the mask signal indicates that the operation clock signal is not masked, and wherein the selector 244 is configured to select the data of the value of 0 if the mask signal indicates that the operation clock signal is masked.

Also, according to the present first embodiment, the arithmetic processing device (e.g., the pre-processing section 24) is configured in which the mask control section 2431 is configured to generate the mask signal for each control unit (e.g., bit control unit BU) in which predetermined flip-flop circuits are collectively set and the mask section 2432 is configured to output the operation clock signal to each corresponding flip-flop circuit for each control unit (e.g., bit control unit BU).

Also, according to the first embodiment, the arithmetic processing device (e.g., the pre-processing section 24) is configured in which the control unit (e.g., the bit control unit BU) is configured to include the flip-flop circuits for which supply of the same operation clock signal is supplied.

Also, according to the present first embodiment, the arithmetic processing device (e.g., the pre-processing section 24) is configured in which the control unit (e.g., the bit control unit BU) is configured to include the flip-flop circuits corresponding to the same bit of data in the flip-flop circuit groups 242 of the each stages.

Also, according to the present first embodiment, for example, the arithmetic processing device (e.g., the pre-processing section 24) is configured in which the mask processing section 243 is disposed between a position at which a clock signal is input (the clock input terminal) and a branch point (a branch point on a path) at which a path (the clock signal line) is branched in the path (the clock signal line) along which the clock signal input to the pre-processing section 24 is supplied as the operation clock signal to each flip-flop circuit.

Also, according to the present first embodiment, the arithmetic processing device (e.g., the pre-processing section 24) is configured in which the mask processing section 243 is disposed between the position at which the clock signal is input (the clock input terminal) and the branch point closest to the position at which the clock signal is input (the clock input terminal).

Also, according to the first embodiment, there is provided an image processing device (the image processing device 20), including: an arithmetic processing device (e.g., the pre-processing section 24) which includes a pipeline in which a combination of the combination circuit 241 and a flip-flop circuit group 242 including a plurality of flip-flop circuits corresponding to each bits of output data of the combination circuit 241 is connected in a plurality of stages and which is configured to control a mask of an operation clock signal to be supplied to each flip-flop circuit on the basis of an input instruction; and a control section (the control section 21) configured to issue an instruction for masking the operation clock signal to be supplied to the flip-flop circuit on the basis of the number of bits of input data (e.g., a pixel signal) to be subjected to an arithmetic process to be input to the arithmetic processing device (e.g., the pre-processing section 24).

Also, according to the present first embodiment, there is provided an image processing device (the image processing device 20) is configured in which the control section 21 is configured to instruct the arithmetic processing device (e.g., the pre-processing section 24) to supply the operation clock signal to each flip-flop circuit corresponding to a bit of the input data (e.g., the pixel signal) for use in the arithmetic process in the combination circuit 241, and the control section 21 is configured to instruct the arithmetic processing device (e.g., the pre-processing section 24) to mask the operation clock signal to be supplied to each flip-flop circuit corresponding to a bit of the input data (e.g., the pixel signal) that is unused in the arithmetic process in the combination circuit 241.

Also, according to the present first embodiment, there is provided an imaging device (the imaging device 1) having a plurality of operation modes, the imaging device 1, including: an image processing device (the image processing device 20) which includes an arithmetic processing device (e.g., the pre-processing section 24) which includes a pipeline in which a combination of the combination circuit 241 and a flip-flop circuit group 242 including a plurality of flip-flop circuits corresponding to each bits of output data of the combination circuit 241 is connected in a plurality of stages and which is configured to control a mask of an operation clock signal to be supplied to each flip-flop circuit on the basis of an input instruction; and a control section (the control section 21) configured to issue an instruction for masking the operation clock signal to be supplied to the flip-flop circuit on the basis of the number of bits of input data (e.g., a pixel signal) to be subjected to an arithmetic process input to the arithmetic processing device (e.g., the pre-processing section 24), wherein the number of bits of the input data (e.g., the pixel signal) differs according to each operation mode (e.g., the still-image capturing mode or a moving-image capturing mode).

Also, according to the present first embodiment, there is provided an imaging device (the imaging device 1) is configured in which the control section 21 is configured to instruct the arithmetic processing device (e.g., the pre-processing section 24) to supply the operation clock signal to each flip-flop circuit corresponding to a bit of the input data (e.g., the pixel signal) for use in the arithmetic process in the combination circuit 241, and the control section 21 is configured to instruct the arithmetic processing device (e.g., the pre-processing section 24) to mask the operation clock signal to be supplied to each flip-flop circuit corresponding to a bit of the input data (e.g., the pixel signal) that is unused in the arithmetic process in the combination circuit 241.

As described above, in the arithmetic processing device of the first embodiment, flip-flop circuits corresponding to the same bit in the flip-flop circuit groups provided in the arithmetic processing device are set as a control unit. In the arithmetic processing device of the first embodiment, the supply (input) of an operation clock signal is controlled for each control unit. Thereby, in the arithmetic processing device of the first embodiment, it is possible to perform control so that the supply (input) of the operation clock signal to the flip-flop circuit corresponding to a bit that is unused in the arithmetic process is not performed. Thereby, in the arithmetic processing device of the first embodiment, it is possible to reduce the consumption of power corresponding to the power consumption when the operation clock signal is supplied (input) to the flip-flop circuit corresponding to a bit that is unused in the arithmetic process.

Also, as shown in FIGS. 3 to 5, in the pre-processing section 24 that is the arithmetic processing device of the first embodiment, the flip-flop circuits corresponding to the same bit in the flip-flop circuit groups 242 are collectively set as each control unit that controls the supply (input) of the operation clock signal. However, as described above, all bits of the 12-bit pixel signal output by the image sensor 10 are a valid pixel signal when the imaging device 1 operates in the still-image capturing mode and a 10-bit pixel signal within the 12-bit pixel signal output by the image sensor 10 is a valid pixel signal when the imaging device 1 operates in the moving-image capturing mode. In other words, a 10-bit pixel signal within the 12-bit pixel signal output by the image sensor 10 is a valid pixel signal all the time regardless of the operation mode of the imaging device 1. This may also indicate that there is a possibility that a bit whose state is not switched will be likely to be included in data to be subjected to an arithmetic process in the arithmetic processing device (here, the pixel signal is not switched to a valid or invalid state) according to the first embodiment of the present invention regardless of the operation mode in the imaging device 1. For this reason, the pre-processing section 24 may be configured to control the supply (input) of the operation clock signal by collectively setting the flip-flop circuits corresponding to the bits whose states are not switched as one control unit.

### Modified Example of First Embodiment

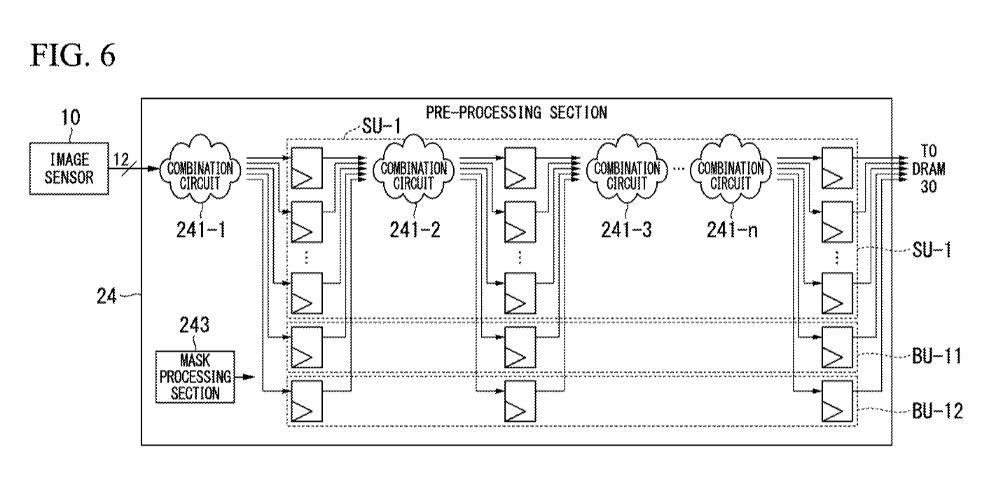

Next, an arithmetic processing device having a configuration in which the supply (input) of an operation clock signal is controlled by collectively setting flip-flop circuits corresponding to bits whose states are not switched included in data to be subjected to an arithmetic process as one control unit (a preprocessing section 24 of a modified example) will be described. FIG. 6 is a diagram schematically showing another method of supplying the clock signal of the pre-processing section 24 of the modified example that is the arithmetic processing device according to the first embodiment of the present invention (a supply method of a modified example). In FIG. 6, a method of controlling an operation clock signal to be supplied (input) to flip-flop circuits constituting each flip-flop circuit group 242 in the pre-processing section 24 of a modified example in which flip-flop circuits corresponding to specific bits whose states are not switched are collectively controlled as one control unit is shown.

More specifically, in the pre-processing section 24 of the modified example shown in FIG. 6, flip-flop circuits for 1^{st} to 10^{th} bits constituting each flip-flop circuit group 242 provided in the pre-processing section 24 are collectively set as a bit set control unit SU-1. Also, in the pre-processing section 24 of the modified example, flip-flop circuits for an 11^{th} bit are collectively set as a bit control unit BU-11 and flip-flop circuits for a 12^{th} bit are collectively set as a bit control unit BU-12.

Also, in the pre-processing section 24 of the modified example shown in FIG. 6, as in the pre-processing section 24 shown in FIG. 3, the mask processing section 243 performs control of the supply (input) of the operation clock signal for achieving and establishing synchronization of the arithmetic operation result output by the corresponding combination circuit 241 for each control unit on the basis of control (an instruction) from the control section 21 provided in the image processing device 20. However, the mask processing section 243 in the pre-processing section 24 of the modified example performs control so that operations of only the flip-flop circuits belonging to the bit control units BU-11 and BU-12 are stopped, i.e., the operation clock signal is not supplied (input), without performing control for stopping operations of the flip-flop circuits belonging to the bit set control unit SU-1.

Also, a case in which a configuration and an operation for controlling the supply (input) of the operation clock signal in the mask processing section 243 in the pre-processing section 24 of the modified example are similar to configurations and operations for controlling the supply (input) of the operation clock signal in the pre-processing sections 24 shown in FIGS. 3 to 5 is conceivable. Accordingly, a detailed description of the configuration and operation in which the mask processing section 243 controls the supply (input) of the operation clock signal in the pre-processing section 24 of the modified example will be omitted.

Also, as described above, the pre-processing section 24 of the modified example does not control the supply (input) of the operation clock signal to each flip-flop circuit belonging to the bit set control unit SU-1. In other words, in the pre-processing section 24 of the modified example, the supply (input) of the operation clock signal is not controlled for the flip-flop circuit corresponding to a 10-bit pixel signal that is valid all the time. Thus, the pre-processing section 24 of the modified example may be configured without having the function of the mask control section 2431 for generating the mask signal corresponding to the bit set control unit SU-1 and the mask section 2432 corresponding to the bit set control unit SU-1. In other words, the pre-processing section 24 of the modified example may be configured to control the supply (input) of the operation clock signal to only the flip-flop circuits corresponding to bits for which data to be subjected to an arithmetic process is switched to a valid pixel signal or an invalid pixel signal in accordance with an operation mode of the imaging device 1.

As described above, also in the arithmetic processing device according to the modified example of the first embodiment, as in the arithmetic processing device of the first embodiment, the supply (input) of the operation clock signal is controlled for each control unit of flip-flop circuits constituting each flip-flop circuit group provided in the arithmetic processing device. Thereby, also in the arithmetic processing device according to the modified example of the first embodiment, as in the arithmetic processing device of the first embodiment, it is possible to perform control so that the supply (input) of the operation clock signal to the flip-flop circuit corresponding to a bit that is unused in the arithmetic process is not performed and reduce the consumption of power corresponding to the power consumption when the operation clock signal is supplied (input) to the flip-flop circuit corresponding to a bit that is unused in the arithmetic process.

Moreover, the arithmetic processing device of the modified example of the first embodiment is able to be configured without having a function of a mask control section 2431 for generating a mask signal corresponding to a control unit (a bit set control unit SU-1) in which the supply (input) of the operation clock signal is not controlled or the mask section 2432. Thus, in the arithmetic processing device of the modified example of the first embodiment, it is possible to reduce a circuit scale of a component for implementing the function of controlling the supply (input) of the operation clock signal as compared with that of the arithmetic processing device of the first embodiment.

Also, an example in which the supply (input) of the operation clock signal is controlled for each bit control unit BU in which flip-flop circuits corresponding to the same bit in the flip-flop circuit groups 242 are collectively set in the pre-processing section 24 that is an arithmetic processing device according to the first embodiment and the modified example of the first embodiment has been described. However, the number of valid bits in the data of the arithmetic operation result output by each combination circuit 241 that performs the pipeline processing in the pre-processing section 24 is not necessarily the same for all the combination circuits 241 provided in the pre-processing section 24. For example, a case in which, if each combination circuit 241 provided in the pre-processing section 24 performs four different arithmetic operations to generate pre-processed image data, the number of valid bits in data of an arithmetic operation result output by each combination circuit 241 differs according to types of four arithmetic operations is conceivable. In other words, a case in which the number of bits of the pixel signal input to the pre-processing section 24 and the number of bits of the pre-processed image data output from the pre-processing section 24 are the same but the number of bits of the data of the arithmetic operation result output by the combination circuit 241 is different in a process of generating pre-processed image data by performing an arithmetic process on a pixel signal is also conceivable. In other words, a case in which the number of valid bits in the data of the arithmetic operation result output by each combination circuit differs according to each combination circuit in the arithmetic processing device is conceivable. Thus, in the arithmetic processing device of the present invention, the setting of the control unit for controlling the supply (input) of the operation clock signal may be set on the basis of the number of valid bits in the data of the arithmetic operation result output by each combination circuit.

### Second Embodiment

Next, an arithmetic processing device according to a second embodiment of the present invention will be described. The arithmetic processing device according to the second embodiment of the present invention is an arithmetic processing device having a configuration in which the number of valid bits in the data of the arithmetic operation result output by each combination circuit differs according to each combination circuit.

Also, in the following description, a case in which an image processing device including the arithmetic processing device according to the second embodiment of the present invention is mounted on an imaging device such as, for example, a still-image camera will be described. The configuration of the imaging device equipped with the image processing device having the arithmetic processing device according to the second embodiment of the present invention is similar to the schematic configuration of the imaging device 1 equipped with the image processing device 20 including the arithmetic processing device according to the first embodiment of the present invention shown in FIG. 1. Accordingly, a detailed description of the configuration of the imaging device equipped with the image processing device including the arithmetic processing device according to the second embodiment of the present invention will be omitted and components similar to the components of the imaging device 1 equipped with the image processing device 20 including the arithmetic processing device according to the first embodiment of the present invention shown in FIG. 1 will be described using the same reference signs.

In the following description, as in the arithmetic processing device according to the first embodiment, a pre-processing section will be described as a representative of the arithmetic processing device of the second embodiment of the present invention. In the following description, the pre-processing section that is the arithmetic processing device of the second embodiment of the present invention is referred to as a “pre-processing section 54” to distinguish the pre-processing section 24 that is the arithmetic processing device according to the first embodiment and the pre-processing section that is the arithmetic processing device of the second embodiment of the present invention.

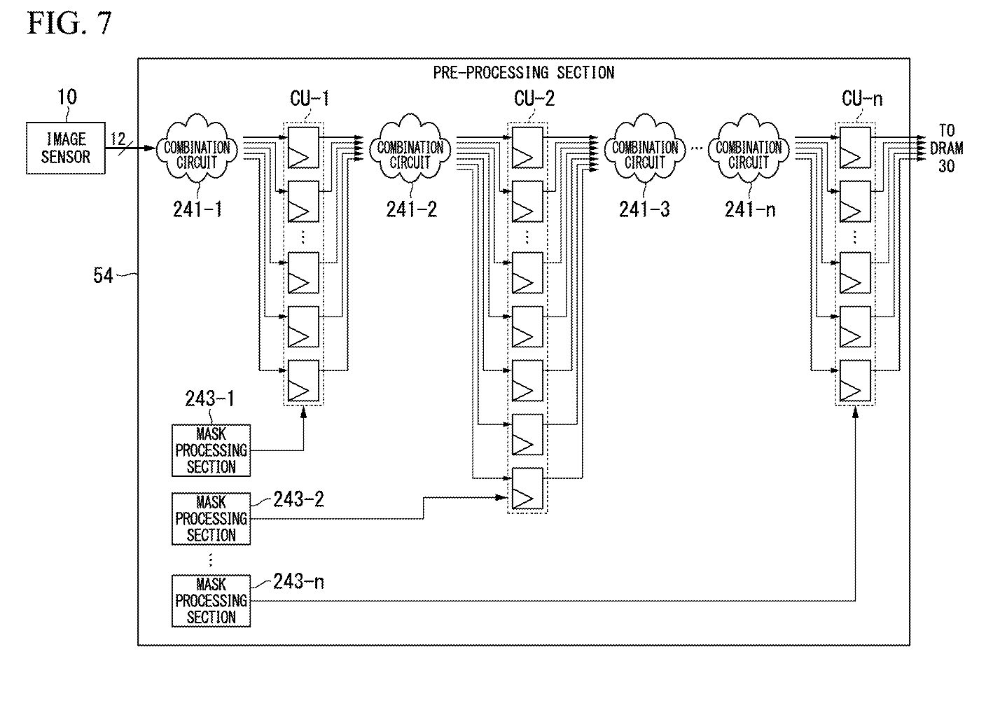

Here, a method of supplying an operation clock signal to each flip-flop circuit in the pre-processing section 54 will be described. FIG. 7 is a diagram schematically showing a method of supplying an operation clock signal of the pre-processing section 54 that is an arithmetic processing device according to the second embodiment of the present invention. In FIG. 7, an example of the pre-processing section 54 in which a combination circuit 241-1 of a 1^{st} stage and a combination circuit 241-n of an n^{th} stage include (12) flip-flop circuits for 12 bits and a combination circuit 241-2 of a 2^{nd} stage includes flip-flop circuits for 14 bits, i.e., 14 flip-flop circuits, is shown.

The pre-processing section 54 shown in FIG. 7 is an arithmetic processing device having a configuration in which the operation clock signal to be supplied (input) to each flip-flop circuit is controlled for each flip-flop circuit group 242 provided in the pre-processing section 54. More specifically, in the pre-processing section 54, the combination circuit 241-1 of the 1^{st} stage is set as a clock supply control unit CU-1, the combination circuit 241-2 of the 2^{nd} stage is set as a clock supply control unit CU-2, the combination circuit 241-n of the n^{th} stage is set as a clock supply control unit CU-n, and the supply (input) of the operation clock signal is controlled for each flip-flop circuit belonging to each clock supply control unit CU. In other words, the pre-processing section 54 controls the supply (input) of the operation clock signal for each flip-flop circuit on the basis of the number of valid bits in data of an arithmetic operation result output by each combination circuit 241. Thus, the pre-processing section 54 is configured to include the function of the mask processing section 243 provided in the pre-processing section 24 that is the arithmetic processing device according to the first embodiment shown in FIG. 4 for each clock supply control unit CU.

In FIG. 7, a mask processing section 243-1 corresponding to the clock supply control unit CU-1, a mask processing section 243-2 corresponding to the clock supply control unit CU-2, and a mask processing section 243-n corresponding to the clock supply control unit CU-n are briefly shown. The mask processing section 243-1 controls the supply (input) of an operation clock signal for each flip-flop circuit belonging to the clock supply control unit CU-1. The mask processing section 243-2 controls the supply (input) of an operation clock signal for each flip-flop circuit belonging to the clock supply control unit CU-2. The mask processing section 243-n controls the supply (input) of an operation clock signal for each flip-flop circuit belonging to the clock supply control unit CU-n.

Also, a case in which a configuration and an operation for controlling the supply (input) of the operation clock signal in each mask processing section 243 in the pre-processing section 54 is similar to the configuration and the operation for controlling the supply (input) of the operation clock signal in the pre-processing section 24 that is the arithmetic processing device according to the first embodiment shown in FIGS. 4 and 5 is conceivable. Accordingly, a detailed description of a configuration and an operation for controlling the supply (input) of the operation clock signal in the pre-processing section 54 will be omitted.

According to such a configuration, when an arithmetic process is performed on a pixel signal of valid bits output from an image sensor 10, the pre-processing section 54 causes only flip-flop circuits corresponding to valid bits in data of the arithmetic operation result output by each combination circuit 241 to be operated. Thereby, similar to the pre-processing section 24 that is the arithmetic processing device in the first embodiment, the pre-processing section 54 is able to also reduce power to be consumed by the operation clock signal supplied (input) to the flip-flop circuit corresponding to data of an invalid bit when the arithmetic process is performed.

Moreover, the pre-processing section 54 is able to control the supply (input) of the operation clock signal for each clock supply control unit CU and for each flip-flop circuit constituting the flip-flop circuit group 242. Thus, the supply (input) of the operation clock signal to each flip-flop circuit in the pre-processing section 54 is able to be controlled more finely than in the pre-processing section 24 that is the arithmetic processing device in the first embodiment. In other words, the pre-processing section 54 is able to control the supply (input) of the operation clock signal in units of flip-flop circuits. Thereby, the pre-processing section 54 is able to more optimally reduce power to be consumed by the operation clock signal supplied (input) to the flip-flop circuit corresponding to the invalid bit data in accordance with the arithmetic process performed by the pre-processing section 54.

According to the present second embodiment, the arithmetic processing device (e.g., the pre-processing section 54) is configured in which the control unit (e.g., the clock supply control unit CU) is configured to include the flip-flop circuits corresponding to different bits of data for each flip-flop circuit group (flip-flop circuit group 242) of each stage.

As described above, also in the arithmetic processing device of the second embodiment, as in the arithmetic processing device of the first embodiment, it is possible to perform control so that the operation clock signal is not supplied (input) to the flip-flop circuit corresponding to the invalid bit that is unused in the arithmetic process. However, the arithmetic processing device of the second embodiment controls an operation clock signal to be supplied (input) to each flip-flop circuit for each flip-flop circuit group provided in the arithmetic processing device. Thereby, in the arithmetic processing device of the second embodiment, even when the number of bits of data of the arithmetic operation result output by each combination circuit is different in the course of the arithmetic process, it is possible to perform control so that only the flip-flop circuit corresponding to the valid bit in data of the arithmetic operation result is operated. Thereby, also in the arithmetic processing device of the second embodiment, as in the arithmetic processing device of the first embodiment, it is possible to reduce the consumption of power corresponding to the power consumption when the operation clock signal is supplied (input) to the flip-flop circuit corresponding to a bit that is unused in the arithmetic process.

Also, in the arithmetic processing device of the second embodiment, as in the arithmetic processing device of the first embodiment, a configuration in which flip-flop circuits corresponding to bits whose states are not switched included in data to be subjected to the arithmetic process are collectively set as one control unit and the supply (input) of the operation clock signal is controlled may be adopted. In other words, also in the arithmetic processing device of the second embodiment, a configuration in which flip-flop circuits for switching the operation or the stopping in a similar manner are collectively set as one control unit may be adopted. Also, in the arithmetic processing device of the second embodiment, as in the arithmetic processing device of the first embodiment, a configuration in which the supply (input) of the operation clock signal is not controlled for a flip-flop circuit corresponding to a bit whose state is not switched may be adopted.

### First Modified Example of Second Embodiment

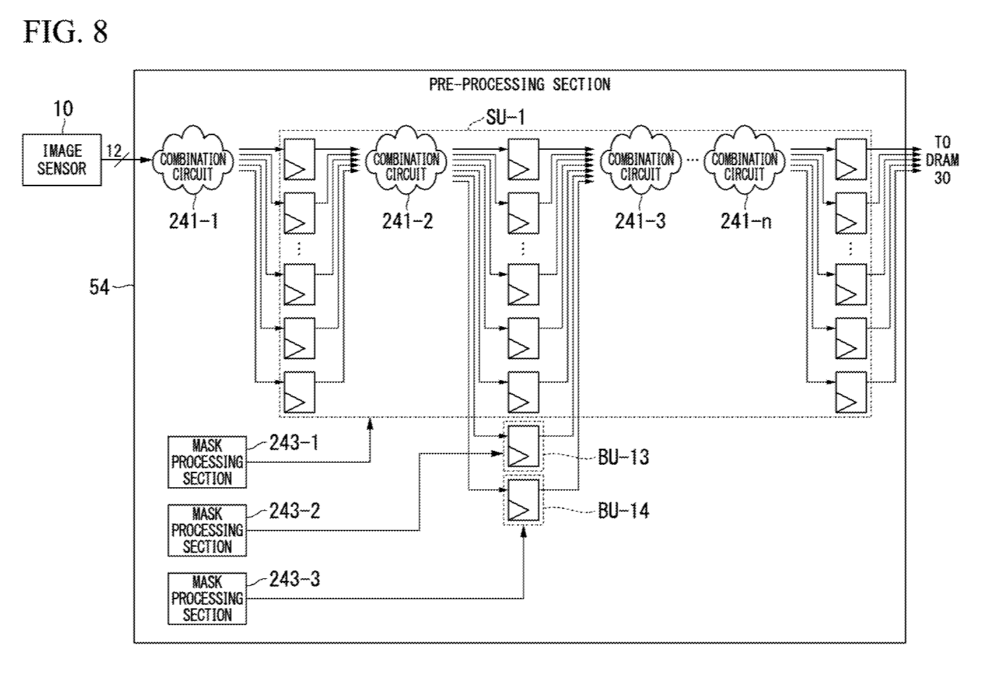

Next, an arithmetic processing device having a configuration in which the supply (input) of an operation clock signal is controlled by designating flip-flop circuits corresponding to bits whose states are not switched included in data to be subjected to an arithmetic process as one control unit (a pre-processing section 54 of a first modified example) will be described. FIG. 8 is a diagram schematically showing another method of supplying a clock signal of the pre-processing section 54 of the first modified example that is an arithmetic processing device according to the second embodiment of the present invention (a supply method of the first modified example).

In FIG. 8, a method of controlling an operation clock signal to be supplied (input) to each flip-flop circuit constituting each flip-flop circuit group 242 in the pre-processing section 54 of the first modified example having a configuration in which control is performed by setting flip-flop circuits corresponding to valid bits in data of arithmetic operation results output by all combination circuits as one control unit is shown.

More specifically, flip-flop circuits for 1^{st} to 12^{th} bits constituting each flip-flop circuit group 242 provided in the pre-processing section 54 are collectively set as a bit set control unit SU-1 in the pre-processing section 54 of the first modified example shown in FIG. 8. Also, in the pre-processing section 54 of the first modified example, a flip-flop circuit for a 13^{th} bit constituting the flip-flop circuit group 242-2 is set as the bit control unit BU-13 and a flip-flop circuit for a 14^{th} bit is set as a bit control unit BU-14.

In the pre-processing section 54 of the first modified example, the mask processing section 243-1 controls the supply (input) of the operation clock signal to each flip-flop circuit belonging to the bit set control unit SU-1. Also, in the pre-processing section 54 of the first modified example, the mask processing section 243-2 controls the supply (input) of the operation clock signal to the flip-flop circuit belonging to the bit control unit BU-13 and the mask processing section 243-3 controls the supply (input) of the operation clock signal to the flip-flop circuit belonging to the bit control unit BU-14.

Also, a case in which a configuration and an operation for controlling the supply (input) of the operation clock signal in each mask processing section 243 in the pre-processing section 54 of the first modified example are similar to the configuration and the operation for controlling the supply (input) of the operation clock signal in the pre-processing section 24 that is the arithmetic processing device in the first embodiment shown in FIGS. 4 and 5 as in the pre-processing section 54 that is the arithmetic processing device in the second embodiment is conceivable. Accordingly, a detailed description of the configuration and operation for controlling the supply (input) of the operation clock signal in the pre-processing section 54 of the first modified example will be omitted.

According to such a configuration, in the pre-processing section 54 of the first modified example, each mask processing section 243 is able to control the supply (input) of the operation clock signal to the corresponding flip-flop circuit if the number of valid bits in the data of the arithmetic operation result output by the combination circuit 241-2 changes in a process of generating pre-processed image data by performing the arithmetic process on the pixel signal output from the image sensor 10. In particular, in the pre-processing section 54 of the first modified example, the mask processing section 243-2 and the mask processing section 243-3 is able to control the supply (input) of the operation clock signal to the flip-flop circuit belonging to the bit control unit BU-13 and the flip-flop circuit belonging to the bit control unit BU-14. Thereby, also in the pre-processing section 54 of the first modified example, as in the pre-processing section 54 that is the arithmetic processing device in the second embodiment, it is possible to reduce power to be consumed by the operation clock signal supplied (input) to the flip-flop circuit corresponding to data of an invalid bit when an arithmetic process is performed. Also, as an example in which each of the mask processing section 243-2 and the mask processing section 243-3 controls the supply (input) of the operation clock signal to the corresponding flip-flop circuit, a case in which the setting of a gain value to be multiplied by a pixel signal for adjusting the brightness of an image or a subject indicated by a pixel signal to fixed brightness changes when the arithmetic process is performed on the pixel signal output by the image sensor 10 or the like is conceived.

Also, if the supply (input) of the operation clock signal to each flip-flop circuit belonging to the bit set control unit SU-1 is not controlled, the pre-processing section 54 of the first modified example may be configured without including the mask processing section 243-1 that controls the supply (input) of the operation clock signal to each flip-flop circuit belonging to the bit set control unit SU-1. In this case, in the pre-processing section 54 of the first modified example, it is possible to reduce the circuit scale of the mask processing section 243-1 as compared with the pre-processing section 54 that is the arithmetic processing device according to the second embodiment.

### Second Modified Example of Second Embodiment

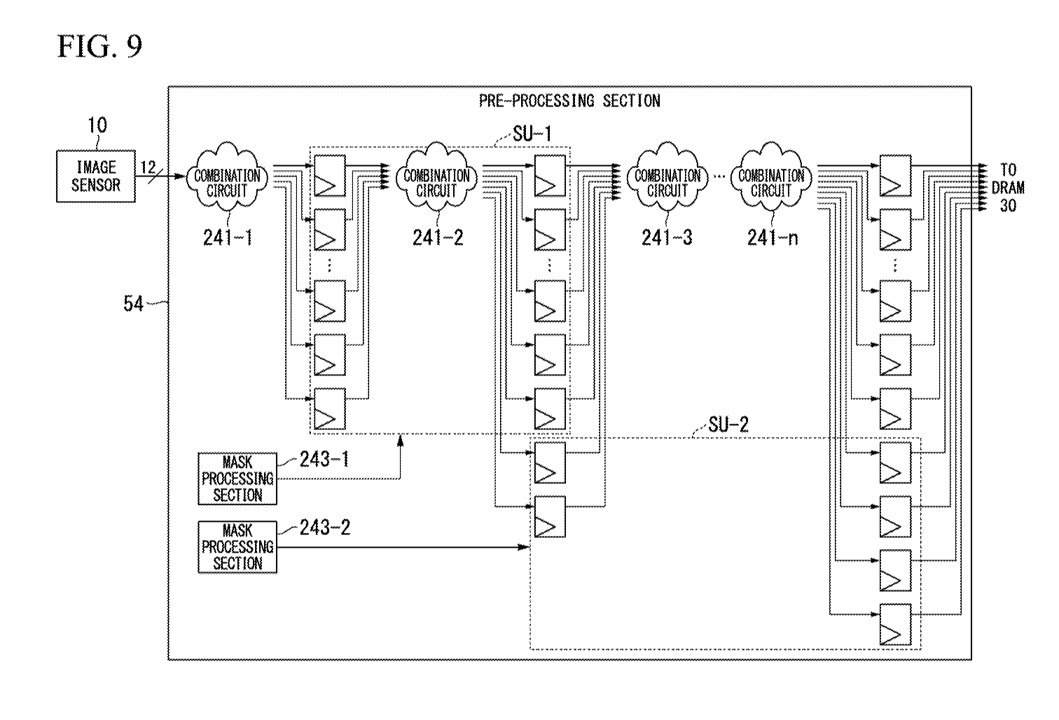

Next, an arithmetic processing device having a configuration in which the supply (input) of an operation clock signal to flip-flop circuits corresponding to bits whose states are not switched is not controlled and the supply (input) of the operation clock signal is controlled by collectively setting flip-flop circuits corresponding to bits in which a valid or invalid state of data to be subjected to the arithmetic process is switched in a similar manner as one control unit (a pre-processing section 54 of a second modified example) will be described. In other words, the pre-processing section 54 of the second modified example having a configuration in which the supply (input) of the operation clock signal is controlled only for flip-flop circuits corresponding to bits for which data to be subjected to an arithmetic process is switched to a valid or invalid state will be described. FIG. 9 is a diagram schematically showing still another method of supplying the clock signal of the pre-processing section 54 of the second modified example that is the arithmetic processing device according to the second embodiment of the present invention (a supply method of the second modified example).

In FIG. 9, a method of controlling the supply (input) of the operation clock signal in the pre-processing section 54 of the second modified example having a configuration in which the supply (input) of the operation clock signal to the flip-flop circuit that operates all the time is not controlled is shown. Also, in the pre-processing section 54 of the second modified example shown in FIG. 9, a configuration in which control is performed by collectively setting flip-flop circuits whose operations are switched in a similar manner in each combination circuit 241 as one control unit and collectively setting the other flip-flop circuits as another one control unit is adopted.

More specifically, in the pre-processing section 54 of the second modified example shown in FIG. 9, flip-flop circuits for 11^{th} and 12^{th} bits constituting a flip-flop circuit group 242-3 provided in the pre-processing section 54 are collectively used as flip-flop circuits for which the supply (input) of the operation clock signal is not controlled. Also, in the pre-processing section 54 of the second modified example, flip-flop circuits for 1^{st} to 12^{th} bits constituting a flip-flop circuit group 242-1 and flip-flop circuits for 1^{st} to 12^{th} bits constituting a flip-flop circuit group 242-2 are collectively set as a bit set control unit SU-1. Also, in the pre-processing section 54 of the second modified example, flip-flop circuits for 13^{th} and 14^{th} bits constituting the flip-flop circuit group 242-2 and flip-flop circuits for 13^{th} to 15^{th} bits constituting the flip-flop circuit group 242-3 are collectively set as a bit set control unit SU-2.

In the pre-processing section 54 of the second modified example, the mask processing section 243-1 controls the supply (input) of the operation clock signal to each flip-flop circuit belonging to the bit set control unit SU-1. Also, in the pre-processing section 54 of the second modified example, the mask processing section 243-2 controls the supply (input) of the operation clock signal to the flip-flop circuit belonging to the bit set control unit SU-2. Also, the pre-processing section 54 of the second modified example does not include the mask processing section 243 for controlling the supply (input) of the operation clock signal to the flip-flop circuits for the 11^{th} and 12^{th} bits constituting the flip-flop circuit group 242-3.

Also, a case in which a configuration and an operation for controlling the supply (input) of the operation clock signal in each mask processing section 243 in the pre-processing section 54 of the second modified example are similar to the configuration and the operation for controlling the supply (input) of the operation clock signal in the pre-processing section 24 that is the arithmetic processing device according to the first embodiment shown in FIGS. 4 and 5 as in the pre-processing section 54 that is the arithmetic processing device in the second embodiment and the first modified example of the second embodiment is conceivable. Accordingly, a detailed description of the configuration and operation for controlling the supply (input) of the operation clock signal in the pre-processing section 54 of the second modified example will be omitted.

According to such a configuration, in the pre-processing section 54 of the second modified example, the mask processing section 243-3 controls the supply (input) of the operation clock signal to the flip-flop circuits belonging to the bit set control unit SU-2. In other words, also in the pre-processing section 54 of the second modified example, in a process of generating pre-processed image data by performing an arithmetic process on a pixel signal output from the image sensor 10, if the number of valid bits in the data of the arithmetic operation results output by the combination circuit 241-2 and the combination circuit 241-3 changes, the mask processing section 243-3 is able to control the supply (input) of the operation clock signal to the corresponding flip-flop circuit. Thereby, also in the pre-processing section 54 of the second modified example, as in the pre-processing section 54 that is the arithmetic processing device according to the second embodiment or the pre-processing section 54 according to the first modified example, it is possible to reduce power to be consumed by the operation clock signal supplied (input) to the flip-flop circuit corresponding to data of an invalid bit when an arithmetic process is performed.

Also, if the supply (input) of the operation clock signal to each flip-flop circuit belonging to the bit set control unit SU-1 is not controlled in the pre-processing section 54 of the second modified example, a configuration in which the mask processing section 243-1 for controlling the supply (input) of the operation clock signal to each flip-flop circuit belonging to the bit set control unit SU-1 is not provided as in the pre-processing section 54 of the first modified example may be adopted. In this case, also in the pre-processing section 54 of the second modified example, as in the pre-processing section 54 of the first modified example shown in FIG. 8, it is possible to reduce the circuit scale of the mask processing section 243-1 as compared with the pre-processing section 54 that is the arithmetic processing device according to the second embodiment.

As described above, also in the arithmetic processing devices of the first modified example and the second modified example of the second embodiment, as in the arithmetic processing device of the first embodiment, the supply (input) of the operation clock signal is controlled for each control unit of flip-flop circuits constituting each flip-flop circuit group provided in the arithmetic processing device. Thereby, also in the arithmetic processing devices of the first modified example and the second modified example of the second embodiment, as in the arithmetic processing device of the first embodiment, it is possible to perform control so that the supply (input) of the operation clock signal to the flip-flop circuit corresponding to a bit that is unused in the arithmetic process is not performed and reduce the consumption of power corresponding to the power consumption when the operation clock signal is supplied (input) to the flip-flop circuit corresponding to a bit that is unused in the arithmetic process.

Moreover, as in the arithmetic processing device of the first modified example of the first embodiment, the arithmetic processing devices of the first modified example and the second modified example of the second embodiment is able to also be configured without having a function of a mask control section 2431 for generating a mask signal corresponding to a control unit (a bit set control unit SU-1) in which the supply (input) of the operation clock signal is not controlled or the mask section 2432. Thus, also in the arithmetic processing devices of the first modified example and the second modified example of the second embodiment, as in the arithmetic processing device of the first modified example of the first embodiment, it is possible to reduce a circuit scale of a component for implementing the function of controlling the supply (input) of the operation clock signal as compared with that of the arithmetic processing device of the second embodiment.

Also, in the arithmetic processing device of the second embodiment (including the arithmetic processing devices of the first modified example and the second modified example), a configuration including the corresponding mask processing sections 243 (the mask processing section 243-1, the mask processing section 243-2, and the like), i.e., a plurality of mask processing sections 243, for each control unit, is shown. However, the mask processing sections 243 provided in the arithmetic processing device of the second embodiment are not limited to the configuration provided for each control unit. For example, one mask processing section 243 for implementing the functions of the plurality of mask processing sections 243 may be configured to be provided in the arithmetic processing device of the second embodiment.

Also, in the first embodiment and the second embodiment, a configuration in which a mask processing section for controlling the supply (input) of the operation clock signal is provided for each arithmetic processing device is shown. However, a case in which control of the supply (input) of the operation clock signal is performed by a plurality of arithmetic processing devices in a similar manner is also conceivable. Accordingly, the mask processing section is not limited to the configuration provided for each arithmetic processing device. For example, each arithmetic processing device may be configured so that the supply (input) of the operation clock signal is controlled by a common mask processing section that performs similar control for a plurality of arithmetic processing devices.

### Third Embodiment

Next, an arithmetic processing device according to a third embodiment of the present invention will be described. The arithmetic processing device according to the third embodiment of the present invention is an arithmetic processing device having a configuration in which the supply (input) of an operation clock signal to each flip-flop circuit is controlled by a common mask processing section without including a mask processing section for controlling the supply (input) of the operation clock signal to the flip-flop circuits constituting each flip-flop circuit group. Also, in the following description, a case in which an image processing device including the arithmetic processing device according to the third embodiment of the present invention is mounted on an imaging device such as, for example, a still-image camera, will be described. Also, an imaging device equipped with the image processing device including the arithmetic processing device according to the third embodiment of the present invention includes components similar to those of the imaging device 1 equipped with the image processing device 20 including the arithmetic processing device according to the first embodiment of the present invention shown in FIG. 1. Accordingly, in the following description, components of the imaging device equipped with the image processing device including the arithmetic processing device according to the third embodiment of the present invention similar to the components of the imaging device 1 equipped with the image processing device 20 including the arithmetic processing device according to the first embodiment of the present invention shown in FIG. 1 are denoted by the same reference signs and a detailed description of the components will be omitted. In the following description, only components different from those of the imaging device 1 equipped with the image processing device 20 including the arithmetic processing device according to the first embodiment will be described.

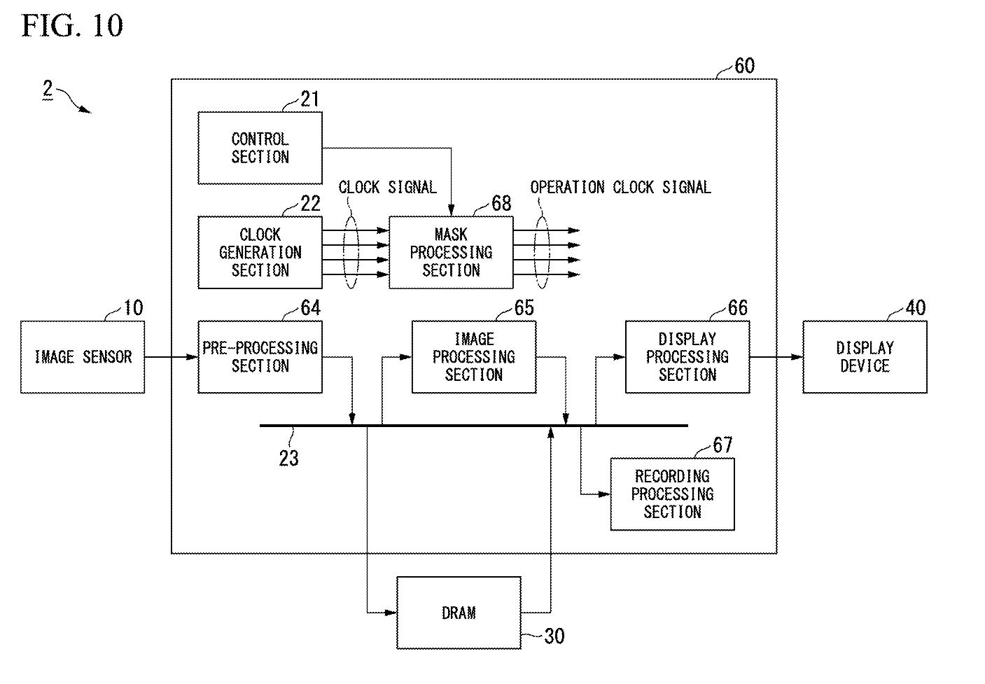

FIG. 10 is a block diagram showing a schematic configuration of the imaging device equipped with the image processing device including the arithmetic processing device according to the third embodiment of the present invention. The imaging device 2 shown in FIG. 10 includes an image sensor 10, an image processing device 60, a DRAM 30, and a display device 40. Also, the image processing device 60 includes a control section 21, a clock generation section 22, a pre-processing section 64, an image processing section 65, a display processing section 66, a recording processing section 67, and a mask processing section 68. In the image processing device 60, each of the pre-processing section 64, the image processing section 65, the display processing section 66, and the recording processing section 67 is connected to a common bus 23 that is a common data bus.

As in the imaging device 1 of the first embodiment shown in FIG. 1, the imaging device 2 also captures an image of a subject with the image sensor 10 and generates a record image and a display image according to the captured image by performing various arithmetic processes on a pixel signal output by the image sensor 10 in the image processing device 60. Similar to the imaging device 1 according to the first embodiment shown in FIG. 1, the imaging device 2 also causes the display device 40 to display the display image generated by the image processing device 60 and causes a recording medium (not shown) to record the record image generated by the image processing device 60.

Similar to the image processing device 20 of the first embodiment shown in FIG. 1, the image processing device 60 generates a record image or a display image by performing a predetermined arithmetic process (image processing) on pixel signals output from the image sensor 10, causes the display device 40 to display the generated display image, and causes the recording medium (not shown) to record the generated record image. The image processing device 60 is configured by replacing the pre-processing section 24, the image processing section 25, the display processing section 26, and the recording processing section 27 provided in the image processing device 20 of the first embodiment shown in FIG. 1 with the pre-processing section 64, the image processing section 65, the display processing section 66, and the recording processing section 67. Also, the image processing device 60 includes the mask processing section 68.

The pre-processing section 64 is an arithmetic processing device that performs pre-processing (an arithmetic process) similar to that of the pre-processing section 24 provided in the image processing device 20 of the first embodiment. However, the pre-processing section 64 is configured without the mask processing section 243 provided in the pre-processing section 24 provided in the image processing device 20 of the first embodiment. More specifically, within the schematic configuration of the pre-processing section 24 shown in FIG. 4, the mask processing section 243 is deleted. The other configuration of the pre-processing section 64 is similar to the schematic configuration of the pre-processing section 24 shown in FIG. 4. In other words, the pre-processing section 64 also includes a plurality of selectors 244 in the schematic configuration of the pre-processing section 24 shown in FIG. 4. Thus, the pre-processing section 64 is configured to receive a mask signal and an operation clock signal from the mask processing section 68. In accordance with each of the mask signal and the operation clock signal input from the mask processing section 68, the pre-processing section 64 generates pre-processed image data by performing pre-processing similar to that of the pre-processing section 24 provided in the image processing device 20 of the first embodiment and causes the generated pre-processed image data to be stored (written) in the DRAM 30 via the common bus 23.

In this manner, the pre-processing section 64 is configured by merely deleting the mask processing section 243 from the schematic configuration of the pre-processing section 24 shown in FIG. 4 and the other configuration and operation thereof are similar to those of the pre-processing section 24 provided in the image processing device 20 of the first embodiment. Accordingly, a detailed description of the configuration and operation of the pre-processing section 64 will be omitted.

The image processing section 65, the display processing section 66, and the recording processing section 67 are also arithmetic processing devices for performing arithmetic processes similar to those of the image processing section 25, the display processing section 26, and the recording processing section 27 included in the image processing device 20 of the first embodiment. The image processing section 65, the display processing section 66, and the recording processing section 67 are similar to the image processing section 25, the display processing section 26, and the recording processing section 27 included in the image processing device 20 of the first embodiment in terms of other configurations or operations, except that the mask processing section is deleted as in the pre-processing section 64 and the mask signal and the operation clock signal are input from the mask processing section 68. Accordingly, a detailed description of configurations and operations of the image processing section 65, the display processing section 66, and the recording processing section 67 will also be omitted.

The mask processing section 68 generates a mask signal for controlling a selector 244 corresponding to a flip-flop circuit for each bit constituting each flip-flop circuit group 242 provided in each arithmetic processing device within the image processing device 60 on the basis of control (an instruction) from the control section 21 provided in the image processing device 60. Also, the mask processing section 68 generates an operation clock signal to be supplied (input) to each flip-flop circuit for each bit constituting each flip-flop circuit group 242 provided in each arithmetic processing device within the image processing device 60 on the basis of the generated mask signal. The mask processing section 68 outputs the generated mask signal and operation clock signal to the corresponding arithmetic processing devices within the image processing device 60.

Instead of the mask processing section 243 provided in each arithmetic processing device in the image processing device 20 of the first embodiment, the mask processing section 68 is commonly provided in the arithmetic processing devices provided in the image processing device 60. Thus, the mask processing section 68 is able to perform the control of supply (input) of the operation clock signal to a plurality of arithmetic processing devices provided in the image processing device 60 in a similar manner.

Also, the configuration and the operation of the mask processing section 68 and the generated mask signal and operation clock signal are similar to those of the mask processing section 243 provided in each arithmetic processing device in the image processing device 20 of the first embodiment. Accordingly, a detailed description of the configuration and the operation of the mask processing section 68 and the generated mask signal and operation clock signal will be omitted.

As described above, also in the arithmetic processing device of the third embodiment, as in the arithmetic processing devices of the first embodiment and the second embodiment, it is possible to control the supply (input) of the operation clock signal to the flip-flop circuit corresponding to a bit that is unused in the arithmetic process. In other words, in the arithmetic processing device of the third embodiment, as in the arithmetic processing devices of the first embodiment and the second embodiment, it is possible to perform control so that the supply (input) of the operation clock signal to the flip-flop circuit corresponding to the bit that is unused in the arithmetic process is not performed. Thereby, also in the arithmetic processing device of the third embodiment, as in the arithmetic processing devices of the first and second embodiments, it is possible to reduce the consumption of power corresponding to the power consumption when the operation clock signal is supplied (input) to the flip-flop circuit corresponding to a bit that is unused in the arithmetic process.

Moreover, in the arithmetic processing device of the third embodiment, the mask processing section for controlling the supply (input) of the operation clock signal is commonly provided in a plurality of arithmetic processing devices. Thus, in the arithmetic processing device of the third embodiment, the common mask processing section is able to perform similar control of the supply (input) of the operation clock signal. Thereby, in the arithmetic processing device of the third embodiment, it is possible to reduce a circuit scale of a component for implementing the function of controlling the supply (input) of the operation clock signal as compared with those of the arithmetic processing devices of the first embodiment and the second embodiment.

Also, in the arithmetic processing device of the third embodiment, a configuration in which a mask processing section common to a plurality of arithmetic processing devices outputs a mask signal and an operation clock signal to a corresponding arithmetic processing device, i.e., a configuration in which a mask processing section including a mask control section and a mask section is provided outside the arithmetic processing device, has been described. However, the configuration of the mask processing section provided outside the arithmetic processing device is not limited to the configuration shown in the arithmetic processing device of the third embodiment. For example, a configuration in which a mask control section constituting the mask processing section is provided outside the arithmetic processing device and a mask section constituting the mask processing section is provided inside each arithmetic processing device may be adopted. In this case, the mask processing section outputs only the mask signal to the corresponding arithmetic processing device and the mask section provided in each arithmetic processing device is configured to perform control so that the supply (input) of the operation clock signal to the flip-flop circuit corresponding to a bit that is unused in the arithmetic process is not performed by masking a clock signal output from the clock generation section in accordance with a mask signal output from the mask processing section. Also, according to this configuration, as in the arithmetic processing device of the third embodiment it is possible to reduce the consumption of power corresponding to the power consumption when the operation clock signal is supplied (input) to the flip-flop circuit corresponding to a bit that is unused in the arithmetic process.

As described above, according to each embodiment of the present invention, only a flip-flop circuit corresponding to data of a bit used for an arithmetic process is operated among flip-flop circuits for temporarily storing (holding) data of an arithmetic operation result output by a combination circuit constituting the arithmetic processing device of the present invention. In other words, in each embodiment of the present invention, the operation of the flip-flop circuit corresponding to the data of the bit that is unused in the arithmetic process is stopped in the arithmetic operation result output by the combination circuit constituting the arithmetic processing device of the present invention. Thereby, in each embodiment of the present invention, it is possible to reduce power to be consumed by supplying (inputting) an operation clock signal to a flip-flop circuit corresponding to data of a bit that is unused in an arithmetic process. Thereby, in each embodiment of the present invention, it is possible to reduce the entire power consumption of the image processing device including the arithmetic processing device of the present invention. In each embodiment of the present invention, it is also possible to reduce the entire power consumption of the imaging device equipped with the image processing device including the arithmetic processing device of the present invention.

Also, in each embodiment of the present invention, the configuration in which the control section provided in the image processing device controls the supply (input) of the operation clock signal (issuing an instruction thereof) has been described. However, the configuration for controlling the supply (input) of the operation clock signal (issuing an instruction thereof) is not limited to the configuration shown in each embodiment of the present invention. For example, a control unit such as a central processing section (CPU) provided in the imaging device and configured to perform overall control of the imaging device may be configured to control the supply (input) of the operation clock signal to the arithmetic processing device provided in the image processing device (issue an instruction thereof).

Also, in each embodiment of the present invention, an example of setting of various control units for controlling the supply (input) of an operation clock signal has been described. However, the control unit set for controlling the supply (input) of the operation clock signal is not limited to the control unit shown in each embodiment of the present invention and it is also possible to control the supply (input) of the operation clock signal in other control units in a similar manner. For example, flip-flop circuit groups including the same number of flip-flop circuits may be set as the same control unit. More specifically, in the pre-processing section 54 that is the arithmetic processing device of the second embodiment shown in FIG. 7, a combination circuit 241-1 of a 1^{st} stage and a combination circuit 241-n of an n^{th} stage may be set as one control unit and the combination circuit 241-2 of a 2^{nd} stage may be set as another one control unit. Also in such setting of the control unit, it is possible to control the supply (input) of an operation clock signal to a flip-flop circuit corresponding to a bit that is unused in the arithmetic process in the arithmetic processing device and to reduce power to be consumed by a flip- flop circuit.

Also, in each embodiment of the present invention, the configuration in which the arithmetic processing device is provided in the image processing device mounted on the imaging device has been described. However, an arithmetic process in which the number of bits of data to be used differs according to an arithmetic operation to be executed is not limited to an arithmetic process on image data, i.e., image processing, but various arithmetic processes besides the image processing are conceivable. For example, a case in which the number of bits of data to be used for an arithmetic operation differs according to an arithmetic operation to be executed with respect to sound sources with different sound qualities (more specifically, high-resolution audio with a high sampling frequency and a large number of quantized bits, low-resolution audio with a low sampling frequency and a small number of quantized bits, or the like) and speech data is conceived. Accordingly, a processing device and a system to which the arithmetic processing device based on the concept of the present invention is able to be applied are not limited to the image processing device and the imaging device described in each embodiment of the present invention. In other words, in any processing device or system for performing an arithmetic process in which the number of bits of data to be used for an arithmetic operation differs according to an arithmetic operation to be executed, an arithmetic processing device based on the concept of the present invention is able to be applied in a similar manner and an effect similar to that of the present invention is able to be obtained.

While preferred embodiments of the present invention have been described and shown above, the present invention is not limited to the embodiments and modified examples thereof. Within a range not departing from the gist or spirit of the present invention, additions, omissions, substitutions, and other modifications to the configuration can be made.

Also, the present invention is not to be considered as being limited by the foregoing description, and is limited only by the scope of the appended claims.

What is claimed is:

1. An arithmetic processing device of a pipeline configuration in which a combination of a combination circuit and a flip-flop circuit group including a plurality of flip-flop circuits corresponding to each bits of output data of the combination circuit is connected in a plurality of stages, the arithmetic processing device comprising:
a mask processing section configured to control a mask of an operation clock signal to be supplied to each flip-flop circuit,
wherein the mask processing section is configured to supply the operation clock signal to each flip-flop circuit corresponding to a bit of the input data for use in the arithmetic process in the combination circuit, and
wherein the mask processing section is configured to mask the operation clock signal corresponding to a bit of the input data that is unused in the arithmetic process in the combination circuit.

2. The arithmetic processing device according to claim 1,
wherein the mask processing section includes;
a mask control section configured to generate a mask signal indicating whether or not to mask the operation clock signal; and
a mask section configured to output an input clock signal or a predetermined fixed level signal as the operation clock signal in accordance with the mask signal,
wherein the flip-flop circuit group includes a selector corresponding to each flip-flop circuit and configured to select and output data held by the corresponding flip-flop circuit or data of a value of 0 on the basis of the mask signal corresponding to the flip-flop circuit,
wherein the selector is configured to select the data held by the corresponding flip-flop circuit if the mask signal indicates that the operation clock signal is not masked, and
wherein the selector is configured to select the data of the value of 0 if the mask signal indicates that the operation clock signal is masked.

3. The arithmetic processing device according to claim 2,
wherein the mask control section is configured to generate the mask signal for each control unit in which predetermined flip-flop circuits are collectively set, and
wherein the mask section is configured to output the operation clock signal to each corresponding flip-flop circuit for each control unit.

4. The arithmetic processing device according to claim 3,
wherein the control unit is configured to include the flip-flop circuits for which supply of the same operation clock signal is supplied.

5. The arithmetic processing device according to claim 3,
wherein the control unit is configured to include the flip-flop circuits corresponding to the same bit of data in the flip-flop circuit groups of the each stages.

6. The arithmetic processing device according to claim 3,
wherein the control unit is configured to include the flip-flop circuits corresponding to different bits of data for each flip-flop circuit group of each stage.

7. The arithmetic processing device according to claim 1,
wherein the mask processing section is disposed between a position at which a clock signal is input and a branch point at which a path is branched in the path along which the clock signal input to the arithmetic processing device is supplied as the operation clock signal to each flip-flop circuit.

8. The arithmetic processing device according to claim 7,
wherein the mask processing section is disposed between the position at which the clock signal is input and the branch point closest to the position at which the clock signal is input.

9. An image processing device, comprising:
an arithmetic processing device which includes a pipeline in which a combination of a combination circuit and a flip-flop circuit group including a plurality of flip-flop circuits corresponding to each bits of output data of the combination circuit is connected in a plurality of stages and which is configured to control a mask of an operation clock signal to be supplied to each flip-flop circuit on the basis of an input instruction; and
a control section configured to issue an instruction for masking the operation clock signal to be supplied to the flip-flop circuit on the basis of the number of bits of input data to be subjected to an arithmetic process to be input to the arithmetic processing device,
wherein the control section is configured to instruct the arithmetic processing device to supply the operation clock signal to each flip-flop circuit corresponding to a bit of the input data for use in the arithmetic process in the combination circuit, and
wherein the control section is configured to instruct the arithmetic processing device to mask the operation clock signal to be supplied to each flip-flop circuit corresponding to a bit of the input data that is unused in the arithmetic process in the combination circuit.

10. An imaging device having a plurality of operation modes, the imaging device comprising:
an image processing device which includes an arithmetic processing device which includes a pipeline in which a combination of a combination circuit and a flip-flop circuit group including a plurality of flip-flop circuits corresponding to each bits of output data of the combination circuit is connected in a plurality of stages and which is configured to control a mask of an operation clock signal to be supplied to each flip-flop circuit on the basis of an input instruction; and
a control section configured to issue an instruction for masking the operation clock signal to be supplied to the flip-flop circuit on the basis of the number of bits of input data to be subjected to an arithmetic process input to the arithmetic processing device,
wherein the control section is configured to instruct the arithmetic processing device to supply the operation clock signal to each flip-flop circuit corresponding to a bit of the input data for use in the arithmetic process in the combination circuit,
wherein the control section is configured to instruct the arithmetic processing device to mask the operation clock signal to be supplied to each flip-flop circuit corresponding to a bit of the input data that is unused in the arithmetic process in the combination circuit, and
wherein the number of bits of the input data differs according to each operation mode.
